(19) United States
(12) Patent Application Publication
(10) Pub. No.: US 2014/0001448 A1
(43) Pub. Date: Jan. 2, 2014

(54) ORGANIC ELECTROLUMINESCENCE DEVICE

(71) Applicant: IDEMITSU KOSAN CO., LTD., (US)

(72) Inventors: Ryo NARAOKA, Sodegaura-shi (JP); Chishio Hosokawa, Sodegaura-shi (JP)

(73) Assignee: IDEMITSU KOSAN CO., LTD., Chiyoda-ku (JP)

(21) Appl. No.: 13/792,600

(22) Filed: Mar. 11, 2013

Related U.S. Application Data
(60) Provisional application No. 61/613,153, filed on Mar. 20, 2012.

(30) Foreign Application Priority Data
Mar. 12, 2012 (JP) 2012-054978

(51) Int. Cl. H01L 51/52

(52) U.S. Cl. CPC H01L 51/5275
USPC 257/40

(57) ABSTRACT

An organic EL device includes: a first electrode; a second electrode, an organic compound layer having an emitting layer, a light-transmissive substrate, a first luminous intensity distribution converter, and a second luminous intensity distribution converter. The first luminous intensity distribution converter has a first convexo-concave structure and converts a luminous intensity distribution for a light flex of an angular component larger than a total reflection angle to account for 20% or more of a total light flux of a radiation light emitted from the emitting layer in the light-transmissive substrate, the total reflection angle being defined by a refractive index of a material forming the light-transmissive substrate and a refractive index of a material forming the first luminous intensity distribution converter. The second luminous intensity distribution converter has a second convexo-concave structure and converts the luminous intensity distribution of the radiation light having entered the light-transmissive substrate to emit the radiation light to an outside of the device.

### CROSS-REFERENCE TO RELATED APPLICATION(S)

The application is based upon and claims the benefit of priority from the prior Japanese Patent Application No. 2012-054978, filed on Mar. 12, 2012, and U.S. Provisional Application No. 61/613153, filed on Mar. 20, 2012; the entire contents of which are incorporated herein by reference.

### FIELD

The present invention relates to an organic electroluminescence device.

### BACKGROUND

An organic electroluminescence device (hereinafter, occasionally referred to as an organic EL device) including an organic thin-film layer (in which an emitting layer is included) between an anode and a cathode, has been known to emit light using exciton energy generated by a recombination at the organic thin-film layer of holes injected from the anode into the emitting layer and electrons injected from the cathode into the emitting layer.

Such an organic EL device, which has the advantages as a self-emitting device, is expected to serve as an emitting device excellent in luminous efficiency, image quality, power consumption and thin design.

In an optical design of such an organic EL device, an optical coherence length is adjusted in order to enhance luminous efficiency. By adjusting a thickness of organic layers such as a hole transporting layer, the luminous efficiency can be effectively enhanced and luminous spectrum can be modulated. Thus, adjustment of the optical coherence length is requisite in designing a device.

However, the light confined in the device cannot be extracted only by adjusting the optical coherence length. Thus, such an arrangement for efficiently extracting the light confined in the device has been proposed (see, for instance, Patent Literature 1: JP-A-2004-296423. Patent Literature 2: JP-A-2010-198881, Patent Literature 3: International Publication No. WO2011/132773).

Patent Literature 1 discloses an organic EL device having a region that disturbs reflection/refraction angles of light emitted from the emitting layer before the light is emitted toward an observer through a transparent electrode. In the organic EL device according to Patent Literature 1, the anode, the cathode and the emitting layer are formed such that a luminance value in a direction of the angle of 50 to 70 degrees becomes larger than a front luminance value in emission light toward the observer from a light-extraction surface.

Patent Literature 2 discloses that a diffractive optical device is provided on a light emission surface of an organic EL device. According to Patent Literature 2, the diffractive optical device provided in the organic EL device diffracts lights that have different main emission wavelengths and are emitted from the emitting layer, thereby changing progressing directions of the lights.

Patent Literature 3 discloses an organic EL device including a light-extraction layer between a transparent electrode and a light-transmissive substrate. The light-extraction layer has a high refractive layer near the transparent electrode and a low refractive layer near the light-transmissive substrate. A convexo-concave structure is formed between the high refractive layer and the low refractive layer.

Although the organic EL devices disclosed in Patent Literatures 1 to 3 can extract light confined within the device to an outside thereof, further improvement of an external quantum efficiency of each of the organic EL devices has been desired for use as a light source of an illumination unit and the like.

### BRIEF SUMMARY OF THE INVENTION

An organic electroluminescence device according to an exemplary embodiment includes: a first electrode; a second electrode opposed to the first electrode; an organic compound layer that is provided between the first electrode and the second electrode and at least comprises an emitting layer, a light-transmissive substrate opposed to a surface of the second electrode facing the first electrode; a first luminous intensity distribution converter that is provided between the second electrode and the light-transmissive substrate, the first luminous intensity distribution converter having a first convexo-concave structure and converting a luminous intensity distribution of a radiation light emitted from the emitting layer to emit the radiation light to the light-transmissive substrate; and a second luminous intensity distribution converter that is provided to a first surface of the light-transmissive substrate opposed to a second surface thereof facing the first luminous intensity distribution converter, the second luminous intensity distribution converter having a second convexo-concave structure and converting the luminous intensity distribution of the radiation light having entered the light-transmissive substrate to emit the radiation light to an outside of the organic electroluminescence device, in which the first luminous intensity distribution converter converts the luminous intensity distribution for a light flux of an angular component larger than a total reflection angle to account for 20% or more of a ratio of a total light flux of the radiation light in the light-transmissive substrate, the total reflection angle being defined by a refractive index of a material forming the light-transmissive substrate and a refractive index of a material forming the first luminous intensity distribution converter.

An organic electroluminescence device according to an exemplary embodiment includes: a first electrode; a second electrode opposed to the first electrode; an organic compound layer that is provided between the first electrode and the second electrode and at least comprises an emitting layer, a light-transmissive substrate opposed to a surface of the second electrode facing the first electrode; a first luminous intensity distribution converter that is provided between the second electrode and the light-transmissive substrate, the first luminous intensity distribution converter converting a luminous intensity distribution of a radiation light emitted from the emitting layer to emit the radiation light to the light-transmissive substrate; and a second luminous intensity distribution converter that is provided to a first surface of the light-transmissive substrate opposed to a second surface thereof facing the first luminous intensity distribution converter, the second luminous intensity distribution converter having a second convexo-concave structure and converting the luminous intensity distribution of the radiation light having entered the light-transmissive substrate to emit the radiation light to an outside of the organic electroluminescence device, in which the first luminous intensity distribution converter converts the luminous intensity distribution for a light flux confined in the light-transmissive substrate when there is no first luminous intensity distribution converter between the second electrode and the light-transmissive substrate to account for 20% or more of a total light flux of the radiation light measured in an outside of the organic EL device when the first luminous intensity distribution converter is present between the second electrode and the light-transmissive substrate.

An organic electroluminescence device according to an exemplary embodiment includes: a first electrode; a second electrode opposed to the first electrode; an organic compound layer that is provided between the first electrode and the second electrode and at least comprises an emitting layer, a light-transmissive substrate opposed to a surface of the second electrode facing the first electrode; a first luminous intensity distribution converter that is provided between the second electrode and the light-transmissive substrate, the first luminous intensity distribution converter converting a luminous intensity distribution of a radiation light emitted from the emitting layer to emit the radiation light so the light-transmissive substrate; and a second luminous intensity distribution converter that is provided to a first surface of the light-transmissive substrate opposed to a second surface thereof facing the first luminous intensity distribution converter, the second luminous intensity distribution converter having a second convexo-concave structure and converting the luminous intensity distribution of the radiation light having entered the light-transmissive substrate to emit the radiation light to an outside of the organic electroluminescence device, in which the first luminous intensity distribution converter comprises: a high refractive layer that is provided near the second electrode; and a low refractive layer that is provided near the light-transmissive substrate and is adjacent to the high refractive layer, and a plurality of convexo-concave units each provided by a convex portion and a concave portion are provided at an interface between the high refractive layer and the low refractive layer.

### BRIEF DESCRIPTION OF THE DRAWINGS

FIG. 1 is a schematic cross-sectional view of an organic EL device according to a first exemplary embodiment that is taken in a thickness direction of a substrate.

FIG. 2 is an illustration for showing a calculation method of a ratio of light in a substrate mode in a total light flux.

FIG. 3A shows a high refractive layer of a first luminous intensity distribution converter of the organic EL device in a planar view from a side of a light-transmissive substrate.

FIG. 3B shows a high refractive layer of the first luminous intensity distribution converter of the organic EL device in a planar view from the side of the light-transmissive substrate.

FIG. 3C shows a high refractive layer of the first luminous intensity distribution converter of the organic EL device in a planar view from the side of the light-transmissive substrate.

FIG. 4 is a schematic cross-sectional view of the organic EL device that is taken in the thickness direction of the substrate and is an illustration for showing a convexo-concave structure of the first luminous intensity distribution converter.

FIG. 5 is a partially enlarged cross section showing an interface between the high refractive layer and a low refractive layer of the first luminous intensity distribution converter of the organic EL device seen in the same direction as in FIG. 4.

FIG. 6A is a perspective view for showing a shape of a second luminous intensity distribution converter of the organic EL device.

FIG. 6B is a perspective view for showing a shape of the second luminous intensity distribution converter of the organic EL device.

FIG. 6C is a perspective view for showing a shape of the second luminous intensity distribution converter of the organic EL device.

FIG. 6D is a perspective view for showing a shape of the second luminous intensity distribution converter of the organic EL device.

FIG. 7 is a schematic cross-sectional view of an organic EL device according to a second exemplary embodiment that is taken in a thickness direction of a substrate.

FIG. 8 is a schematic cross-sectional view of an organic EL device according to a third exemplary embodiment that is taken in a thickness direction of a substrate.

FIG. 9A is a perspective view of a second luminous intensity distribution converter of an organic EL device according to a fourth exemplary embodiment.

FIG. 9B is a cross-sectional view of the second luminous intensity distribution converter of the organic EL device according to the fourth exemplary embodiment.

FIG. 9C is a plan view of the second luminous intensity distribution converter of the organic EL device according to the fourth exemplary embodiment.

FIG. 10 is a plan view for showing a second luminous intensity distribution converter of an organic EL device according to a fifth exemplary embodiment.

FIG. 11A is a perspective view of a second luminous intensity distribution converter of an organic EL device according to a sixth exemplary embodiment

FIG. 11B is a cross-sectional view of the second luminous intensity distribution converter of the organic EL device according to the sixth exemplary embodiment.

FIG. 11C is a plan view of the second luminous intensity distribution converter of the organic EL device according to the sixth exemplary embodiment.

FIG. 12 is a plan view for showing a second luminous intensity distribution converter of an organic EL device according to a seventh exemplary embodiment.

FIG. 13 is a cross sectional view for showing another shape of the second luminous intensity distribution converter.

FIG. 14A shows a high refractive layer having a shape different from that of the first luminous intensity distribution converter in a planar view from the side of the light-transmissive substrate.

FIG. 14B shows a high refractive layer having a shape different from that of the first luminous intensity distribution converter in a planar view from the side of the light-transmissive substrate.

FIG. 15 is a schematic view for showing an evaluation method of luminous intensity distribution of light emitted from an emitting layer of an organic EL device in Examples and the like.

FIG. 16 shows comparison among luminous intensity distribution charts of organic EL devices in References.

FIG. 17 shows comparison among luminous intensity distribution charts of organic EL devices in Examples and Comparative.

FIG. 18A is a schematic view of an arrangement of an organic EL device for checking light flux ratios in the luminous intensity distribution charts.

FIG. 18B is a schematic view of an arrangement of the organic EL device for checking light flux ratios in the luminous intensity distribution charts.

### DETAILED DESCRIPTION OF THE INVENTION

### First Exemplary Embodiment

A first exemplary embodiment of the invention will be described below with reference to the attached drawings.

### Organic Electroluminescence Device

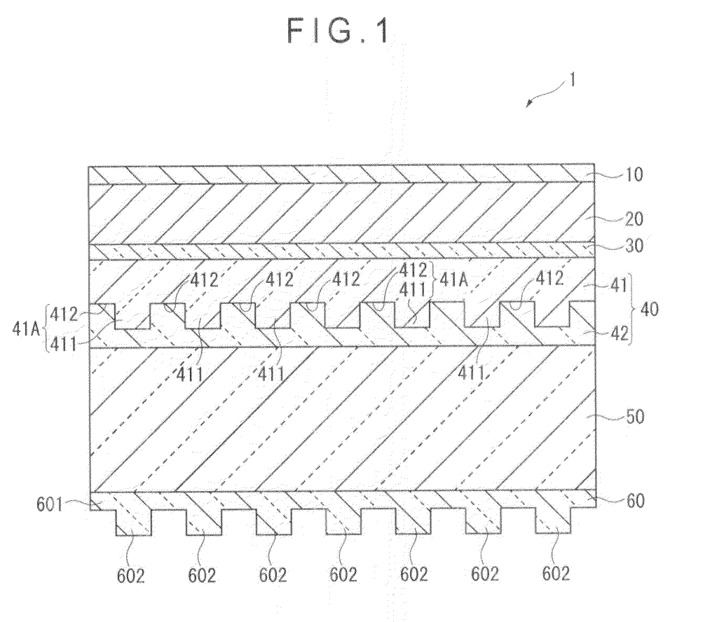

FIG. 1 is a schematic cross-sectional view of an organic EL device 1 according to a first exemplary embodiment that is taken in a thickness direction of a substrate.

The organic EL device 1 is provided by laminating a first electrode 10, an organic compound layer 20, a second electrode 30, a first luminous intensity distribution converter 40, a light-transmissive substrate 50, and a second luminous intensity distribution converter 60 in this sequence.

### Light-Transmissive Substrate

The light-transmissive substrate 50 is a flat and smooth plate member for supporting the first electrode 10, the organic compound layer 20, the second electrode 30, the first luminous intensity distribution converter 40, and the second luminous intensity distribution converter 60. The organic EL device 1 is a so-called bottom-emission device in which radiation light emitted from the organic compound layer 20 is extracted toward the light-transmissive substrate 50. Thus, the light-transmissive substrate 50 is provided by a light-transmissive member that preferably has a light transmittance of 50% or more in a visible light range of 400 nm to 700 nm. Specifically, the light-transmissive substrate 50 are provided by a glass plate, a polymer plate and the like. For the glass plane, such materials as soda-lime glass, barium/strontium-containing glass, lead glass, aluminosilicate glass, borosilicate glass, barium borosilicate glass, quartz and the like can be used. For the polymer plate, materials such as polycarbonate resins, acryl resins, polyethylene terephthalate resins, polyether sulfide resins and polysulfone resins can be used. A refractive index n₂ of the light-transmissive substrate 50 is preferably in a range of 1.4 to 1.6.

### First Electrode

The first electrode 10 is provided adjacent to the organic compound layer 20. An electrode material is used for the first electrode 10.

The first electrode 10 is preferably formed of a light-reflective material such as a metal (e.g. Al, Cu, Ag and Au) and an alloy.

The first electrode 10 may be single-layered or, alternatively may be multilayered. The layers formed by light-reflective material(s) may be laminated. Alternatively, a layer provided by a transparent conductive member and a layer provided by a light-reflective material may be laminated.

### Second Electrode

The second electrode 30 is provided between and adjacent to the organic compound layer 20 and the first luminous intensity distribution converter 40 while being opposed to the first electrode 10 across the organic compound layer 20. In the exemplary embodiment as described above, in order to extract the radiation light emitted from the organic compound layer 20 through the light-transmissive substrate 50 to the outside of the device, the second electrode 30 is provided by a transparent electrode. In this arrangement, the second electrode 30 preferably has a light transmittance exceeding 10% in a visible light range. Sheet resistance of the second electrode 30 is preferably several hundreds Ω/square or less. A thickness of the second electrode 30 is typically in the range of 10 nm to 1 μm, and preferably in the range of 10 nm to 200 nm, though it depends on the material of the second electrode 30.

In this exemplary embodiment, the second electrode 30 is an anode and the first electrode 10 is a cathode. It should be noted that the second electrode 30 may alternatively be a cathode and the first electrode 10 may alternatively be an anode.

An electrode material is used for the second electrode 30. Examples of the electrode material include transparent electrode materials such as ITO (indium tin oxide), IZO (tradename) (indium zinc oxide) and ZnO (zinc oxide). A refractive index n₁ of the second electrode 30 is preferably in a range of 1.8 to 2.2.

### Organic Emitting Layer

The organic emitting layer 20 is provided between the first electrode 10 and the second electrode 30. The organic compound layer 20 is single-layered or multilayered. At least one layer of the organic-compound layer 20 is an emitting layer. Accordingly, the organic compound layer 20 may be provided by a single emitting layer. Alternatively, the organic compound layer 20 may be provided by layers applied in a known organic EL device such as a hole injecting layer, a bole transporting layer, an electron injecting layer, an electron transporting layer, a hole blocking layer, and an electron blocking layer. The organic compound layer 20 may include an inorganic compound.

The organic compound layer 20, which is formed of emitting materials such as Alq₃ (tris(8-hydroxyquinolinato)aluminium), provides a single-color emission such as red, green, blue or yellow emission, and combined-color emission of red, green, blue and yellow emission (e.g., white emission). In forming the emitting layer, a doping method, according to which an emitting material (dopant material) is doped to a host material, has been known as a usable method. The emitting layer formed by the doping method can efficiently generate excitons from electric charges injected into the best material. With the exciton energy generated by the excitons being transferred to the dopant material, the dopant material can emit light with high efficiency. In the exemplary embodiment of the invention, the emitting layer may be provided by a fluorescent emitting layer using emission by singlet excitons, or may alternatively be provided by a phosphorescent emitting layer using emission by triplet excitons.

In the organic compound layer 20 of the organic EL device 1, in addition to the above-mentioned compounds, any compound selected from compounds used in an organic EL device can be selectively used.

### First Luminous Intensity Distribution Converter

The first luminous intensity distribution converter 40 converts a luminous intensity distribution of a radiation light emitted from the organic compound layer 20 to emit the radiation light to the light-transmissive substrate 50.

The first luminous intensity distribution converter 40 converts the luminous intensity distribution for a light flux of an angular component larger than a total reflection angle to account for 20% or more of a total light flux of the radiation light in the light-transmissive substrate 50, the total reflection angle being defined by a refractive index of a material forming the light-transmissive substrate 50 and a refractive index of a material forming the first luminous intensity distribution converter 40.

In another viewpoint, the first luminous intensity distribution converter 40 converts the luminous intensity distribution to provide 20% or more of the ratio of the light flux confined in the light-transmissive substrate 50 when there is no first luminous intensity distribution converter 40 between the second electrode 30 and the light-transmissive substrate 50 in the total light flux of the radiation light measured in the outside of the organic EL device when the first luminous intensity distribution converter 40 is present between the second electrode 30 and the light-transmissive substrate 50.

In other words, the first luminous intensity distribution converter 40 converts the luminous intensity distribution to provide 20% or more of the ratio of light in the substrate mode in the total light flux of the radiation light in the light-transmissive substrate 50. Herein, the light in the substrate mode refers to a component of light confined within the light-transmissive substrate by a total reflection at an interface between air and the light-transmissive substrate. A critical angle where the total reflection occurs is defined as an angle that is formed by a direction of the radiation light and a normal direction of the second electrode and that is determined by a difference in a refractive index between the light-transmissive substrate and the outside. A loss of light in a device arrangement for extracting light in a direction in which a light-transmissive substrate for supporting the organic compound layer is located is roughly classified into the following modes: (i) a mode of light confined within the light-transmissive substrate by a total reflection at an interface between the light-transmissive substrate and air (substrate mode), (ii) a mode of light confined within the transparent electrode and the organic compound layer by a total reflection at an interface between the second electrode (transparent electrode) and the organic compound layer (thin-film mode); and (iii) a mode of light absorbed by the first electrode (metal electrode) as a surface plasmon (surface plasmon mode).

Herein, a case where the ratio of light in the substrate mode is 20% or more refers to a case where an area occupied by the light in the substrate mode relative to an area of the total light flux accounts for 20% or more area in a luminous intensity distribution chart when the luminous intensity distribution is measured after a hemispheric lens is attached to a light-extraction surface of the light-transmissive substrate 50 of the organic EL device 1 with no second luminous intensity distribution converter 60. In other words, provision of the first luminous intensity distribution converter 40 between the light-transmissive substrate 50 and the second electrode 30 allows the ratio of the light in the substrate mode in the light-transmissive substrate 50 to account for 20% or more of the total incident light flux.

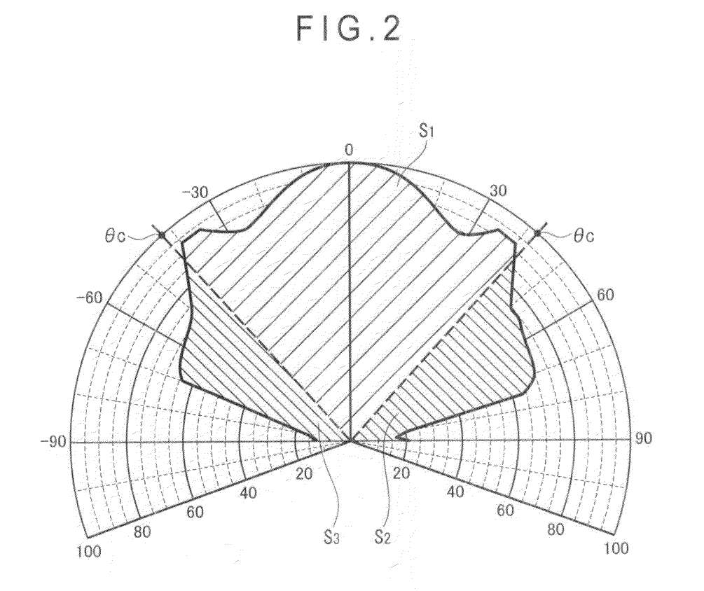

For describing the calculation of the ratio of the light in the substrate mode, a luminous intensity distribution chart of an organic EL device attached with a hemispheric lens is shown in FIG. 2. The light in the substrate mode is, as described above, a component of light confined within the light-transmissive substrate 50 by a total reflection at an interface between air and the light-transmissive substrate 50. A critical angle θe where the total reflection occurs is shown in FIG. 2. In the luminous intensity distribution chart shown in FIG. 2, a component of light at angles larger than the critical angle θc corresponds to the light in the substrate mode. Areas occupied by the light in the substrate mode are represented by a region S2 and a region S3. An area of the light of the total light flux corresponds to a total area of a region S1 at angles smaller than the critical angle θc and the regions S2 and S3 in FIG. 2. Accordingly, the ratio of the light in the substrate mode can be calculated by a formula:

{(S2+S3)/(S1+S2+S3)}×100.

In the organic EL device 1 according to the exemplary embodiment, the P polarized light component of the radiation light refers to a component of light in a vibration direction in parallel to an incident surface, the incident surface being defined as a surface containing the radiation light and a normal of a surface of the light-transmissive substrate. A component of light in the vibration direction perpendicular to the incident surface is defined, as an S polarized light component. The P polarized light component of the radiation light is radiated from luminescent molecules oriented in a direction perpendicular to an emission surface and propagates in a direction along the surface of the light-transmissive substrate, so that radiation light toward higher angles in the luminous intensity distribution is likely to be increased.

The first luminous intensity distribution converter 40 is provided between the light-transmissive substrate 50 and the second electrode 30.

The first luminous intensity distribution converter 40 is provided by laminating a high refractive layer 41 and a low refractive layer 42 in this sequence on the second electrode 30. The low refractive layer 42 is adjacent to the light-transmissive substrate 50. The refractive index of the high refractive layer 41 is higher than that of the low refractive layer 42. A thickness of the high refractive layer 41 is formed to be equal to or more than an optical coherence length.

In the exemplary embodiment, the optical coherence length of the first luminous intensity distribution converter is defined by:

(optical coherence length)=λ²/{n₁₁(Δλ)}.

Herein, λ is a peak wavelength of an emission spectrum of radiation light generated in an organic emitting layer. Δλ is a half bandwidth of the emission spectrum. n_{H} is a refractive index of the high refractive layer.

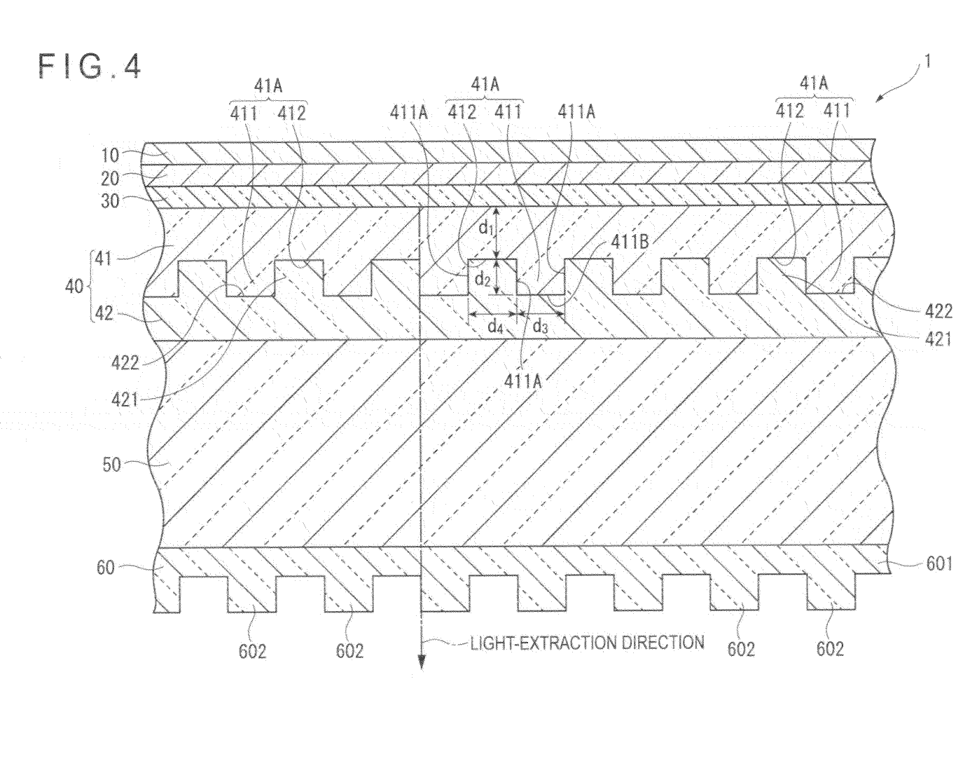

Further, as shown in FIG. 4, the high refractive layer 41 has a plurality of convexo-concave units 41A (i.e., a first convexo-concave structure) provided by convex portions 411 and concave portions 412 at an interface with the low refractive layer 42. As shown in FIG. 1, the convex portions 411 project from the second electrode 30 toward the light-transmissive substrate 50 in a substantially columnar shape and have a substantially rectangular cross section.

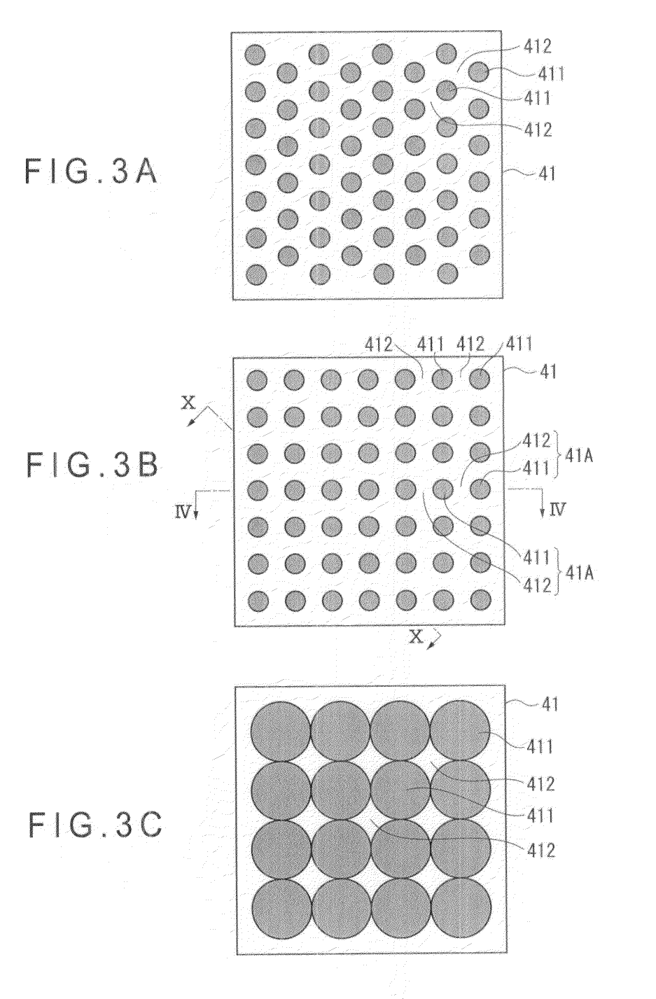

FIGS. 3A, 3B and 3C are plan views showing a part of the high refractive layer 41 from the side of the light-transmissive substrate 50. In these drawings, the low refractive layer 42 and the light-transmissive substrate 50 are omitted for the convenience of illustration. FIGS. 3A, 3B and 3C exemplarily illustrate a plurality of arrangement patterns of the convex portions 411 and the concave portions 412 of the high refractive layer 41.

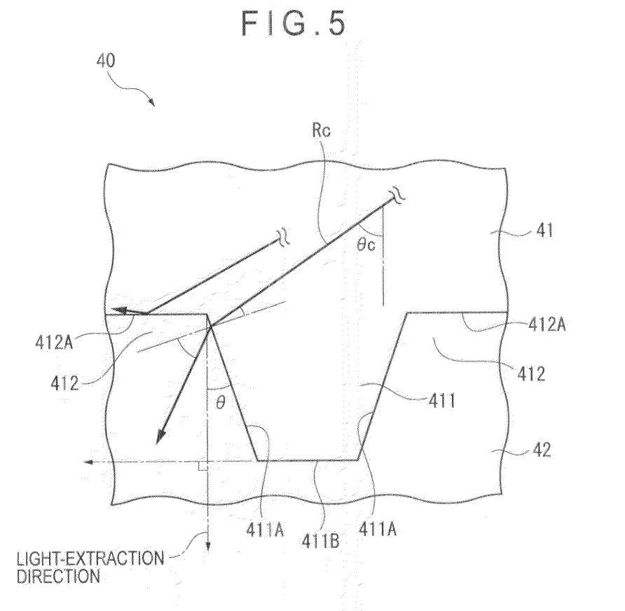

In the arrangement patterns, the convex portions 411 may be arranged in a matrix as shown in FIG. 3B, in a close-pack structure as shown in FIG. 3A or in a manner so that the convex portions 411 are in contact with one another as shown in FIG. 3C as long as dimensional relationships of the high refractive layer 41 and the convexo-concave unit 41A (mentioned below) are satisfied. Further, the convex portions 411 may be arranged in a manner different from the above. The convex portions 411 and the concave portions 412 may be reversely arranged. Specifically, the concave portions 412 may be provided at the position of the convex portions 411 in FIG. 5 so that the high refractive layer 41 may be provided with holes.

In the first exemplary embodiment, the high refractive layer 41 with the arrangement pattern shown in FIG. 3B is provided.

FIG. 4 is a schematic cross-sectional view of the organic EL device 1 according to the first exemplary embodiment that is taken in a thickness direction of the substrate and illustrates a detailed description of the convexo-concave structure of the first luminous intensity distribution converter 40. FIG. 4 is a cross-sectional view taken along IV-IV line in FIG. 3B and seen in the direction of arrow.

In consequence of a multiple number of the convex portions 411, the concave portions 412 are formed where the convex portions 411 are not disposed. As shown in FIG. 4, the convex portions 411 and the concave portions 412 are alternately and continuously formed in cross section. One of the convex portions 411 and one of the concave portions 412 form the convexo-concave unit 41A. Since the low refractive layer 42 is laminated with the high refractive layer 41, the low refractive layer 42 has a concave portion 422 corresponding to the convex portion 411 and a convex portion 421 corresponding to the concave portion 412 of the convexo-concave unit 41A.

FIG. 5 is a partially enlarged cross-sectional view showing an interface between the high refractive layer 41 and the low refractive layer 42 of the first luminous intensity distribution converter 40 seen in the same direction as in FIG. 4.

An inclination angle θ for a side face (convex-portion side face) 411A along a height direction of the convex portion all relative to the light-extraction direction of the organic EL device 1 (i.e. a direction from the organic compound layer 20 toward the light-transmissive substrate 50: a direction orthogonal to a surface of the light-transmissive substrate 50) is preferably 35 degrees or less. By setting the inclination angle θ of the convex-portion side face 411A at 35 degrees or less, light Rc entering the interface between the high refractive layer 41 and the low refractive layer 42 at an angle equal to or more than the critical angle θc can be efficiently introduced into the low refractive layer 42.

In this exemplary embodiment, the inclination angle θ is set approximately at 0 degree. Accordingly, the side face of the convex portion 411 is shaped along the light-extraction direction. Further, an upper face (convex-portion upper face) 411B along a width direction of the convex portion 411 is orthogonal to the light-extraction direction. A lower face 412A of the concave portion 412 of the convexo-concave unit 41A (in other words, an upper face of the convex portion of the low refractive layer 42 seen from the side of the low refractive layer 42) is also shaped along the direction orthogonal to the light-extraction direction.

In this exemplary embodiment, the dimensions of the first luminous intensity distribution converter 40 and the convexo-concave unit 41A are defined according to the optical coherence length or a predetermined value. Initially, a distance d₁ from the interface between the high refractive layer 41 and the second electrode 30 to the interface between the high refractive layer 41 and the low refractive layer 42 is equal to or longer than the optical coherence length.

Further, a height d₂ and a width d₃ of the convex portion 411 and a gap d₄ between the convex portion 411 forming one of the convexo-concave units 41A and the convex portion 411 forming another one of the convexo-concave units 41A are 1 μm or more, preferably, 5 μm or more and further preferably 20 μm or more.

In order that the first luminous intensity distribution converter 40 efficiently guides a light in a thin-film mode into the light-transmissive substrate 50 to provide 20% or more of the ratio of the light in the substrate mode as described above, a height d₂ and a width d₃ of the convex portion 411 and a gap d₄ between the convex portions 411 are preferably 1 mm or less.

The height d₂ represents a distance between a straight line passing through the upper face of the convex portion 411 and extending along the surface of the light-transmissive substrate 50 and a straight line passing through the lower lace of the concave portion 412 and extending along the surface of the light-transmissive substrate 50 when the cross section of the organic EL device 1 is seen as shown in FIG. 4.

The width d₃ represents a distance between right and left convex-portion side faces 411A of the convex portion 411 in a direction along the light-transmissive substrate 50 when the cross section of the organic EL device 1 is seen as shown in FIG. 4.

The gap d₄ represents a distance between one of right and left convex-portion side faces 411A of the convex portion 411 and another convex-portion side face 411A opposing to the one of right and left convex-portion side faces 411A across the concave portion 412 in a direction along the surface of the light-transmissive substrate 50 when the cross section of the organic EL device 1 is seen as shown in FIG. 4.

The height d₂ and the width d₃ of the convex portion 411 preferably satisfy a relationship of 2.0>d₂/d₃>0.2, which is satisfied in this exemplary embodiment. More preferably, the height d₂ and the width d₃ of the convex portion 411 satisfy a relationship of 1.0>d₂/d₃>0.5. When the above relationship is satisfied, the light transmitted to the convexo-concave unit 41A at the interface between the high refractive layer 41 and the low refractive layer 42 can be further efficiently transmitted to the low refractive layer 42, so that the radiation light can efficiently be guided into the light-transmissive substrate 50. When d₂/d₃ is larger than 2.0 (i.e. when the aspect ratio becomes large), the light refracted at the convex-portion side face 411A is likely to again enter the adjacent convex portion 411 to cause a multiple reflection and the like, thereby reducing the light-extraction efficiency.

In the exemplary embodiment, an explanation will be given below on a sectioned position when an organic EL device is seen in cross section in a thickness direction of a transmissive substrate. In the exemplary embodiment of the invention, a cross section obtained by cutting an organic EL device along a crosscutting line passing through at least two adjoining convexo-concave units in plan view of the convexo-concave unit is observed. The direction and positional condition of the crosscutting line can be defined in a variety of ways. However, it is only necessary for the exemplary embodiment of the invention that the dimension of the light-extraction layer and the convexo-concave unit defined by the optical coherence length is preferably satisfied when a cross section is cut out in one direction and positional relationship.

Further, as described above, the organic compound layer 20 is occasionally provided by a laminate of organic emitting layers capable of independently emitting light. In such an arrangement, the optical coherence length is measured on the basis of the largest one of peak wavelengths of the radiation light generated by the plurality of organic emitting layers. For instance, when the organic compound layers each emitting red, green and blue lights are laminated and these emission colors are combined to emit white light from the organic EL device, since the peak wavelength of the red light is the largest, the optical coherence length is defined on the basis of the peak wavelength of the red light.

In such a case, in order to measure a half bandwidth for calculating the optical coherence length, the half bandwidth is assumed to be defined by an emission spectrum of red-emitting molecules. For instance, when the peak wavelength is 610 nm and the half bandwidth is 10 nm, the optical coherence length is approximately 20 μm. Further, in order to obtain an illumination unit with excellent color rendering property, it is preferable that luminous molecules with large half bandwidth of the emission peak are used. For instance, when the half bandwidth of the emission peak is 60 nm, the optical coherence length is approximately 3.5 μm. Accordingly, a preferable range of the distance d₁ of the high refractive layer 41 is 3 μm or more. Further, since the thickness of a practically used illumination panel is approximately 1 mm, the thickness of the high refractive layer 41 is preferably 1 mm or less.

The high refractive layer 41 is formed by, for instance, a sol-gel reaction of an inorganic oxide such as titanium-series metalloxane polymer. Alternatively, the high refractive layer 41 may be formed by dispersing particles of inorganic oxides and the like such as titania and zirconia that exhibit high refractive index on a general-purpose resin and subjecting to a coating method such as spin coating. Further, an episulfide resin material and the like may be used.

A refractive index n_{H} of the high refractive layer 41 is preferably in a range of 1.8 to 2.2. A material for forming the convex portion 411 of the high refractive layer 41 may be different from that for forming the other part. In this case, it is preferable that the refractive indexes of both of the materials are set equal or the refractive index of the convex portion 411 is set lower.

Examples of the material for forming the low refractive layer 42 include a glass material and a polymer material. Examples of the glass material include soda-lime glass, barium/strontium-containing glass, lead glass, aluminosilicate glass, borosilicate glass, barium borosilicate glass and quartz. For the polymer material, materials such as polycarbonate resins, acryl resins, polyethylene terephthalate resins, polyether sulfide resins, polysulfone resins and cycloolefin resins can be used. A refractive index n_{L}, of the low refractive layer 42 is preferably in a range of 1.4 to 1.6. A material for forming the convex portion 421 of the low refractive layer 42 may be different from that for forming the other part. In this case, it is preferable that the refractive indexes of both of the materials are set equal or the refractive index of the convex portion 421 is set higher than the refractive index of the other part.

### Second Luminous Intensity Distribution Converter

The second luminous intensity distribution converter 60 is provided adjacent to a surface opposed to a surface facing the first luminous intensity distribution converter 40 of the light-transmissive substrate 50. The second luminous intensity distribution converter 60 converts the luminous intensity distribution of the radiation light having entered the light-transmissive substrate 50 to emit the radiation light to the outside. The second luminous intensity distribution converter 60 converts the angle of the light in the substrate mode having entered the light-transmissive substrate 50 toward a normal of the surface of the light-transmissive substrate 50, thereby converting the light in the substrate mode into light to be emitted to the outside of the device (i.e., light in a radiation mode). The second luminous intensity distribution converter 60 emits light in a radiation mode having entered the light-transmissive substrate 50 to the outside of the device.

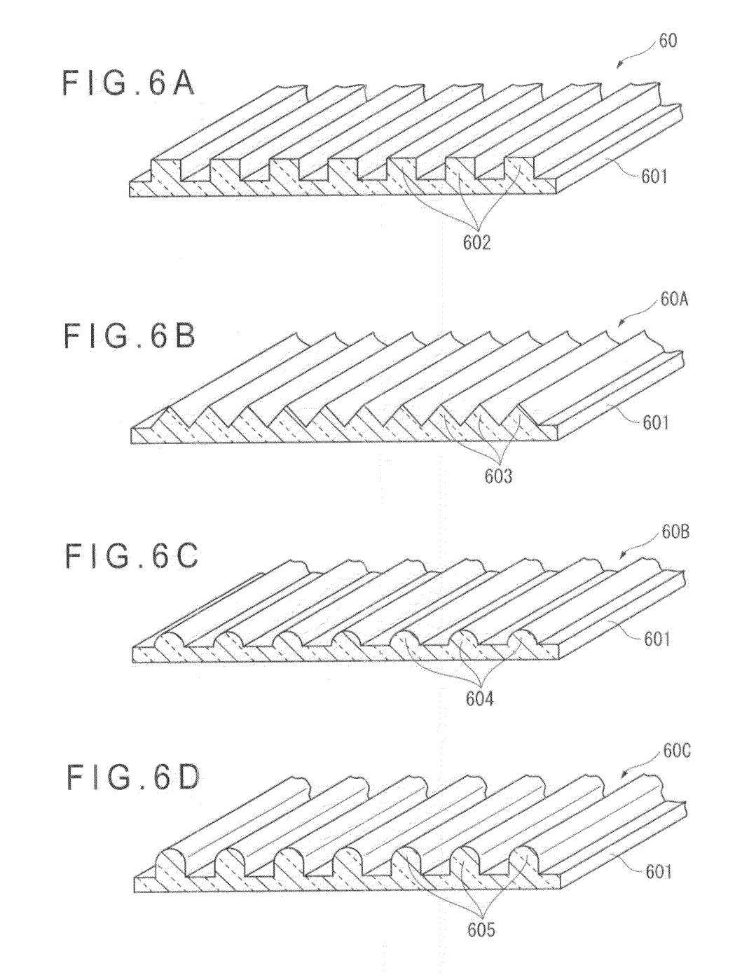

FIG. 6A is a perspective view of the second luminous intensity distribution converter 60 in the exemplary embodiment. As shown in FIGS. 1, 4, 6A, 6B, 6C and 6D, the second luminous intensity distribution converter 60 includes: a base 601 provided adjacent to the light-extraction surface of the light-transmissive substrate 50; and a convex portion 602 (a second convex portion) of the exemplary embodiment which projects from the base 601 in the light extraction direction. The convex portion 602 is rectangular when the organic EL device 1 is cross-sectionally seen in the thickness direction. A plurality of convex portions 602 are formed in stripes. A concave portion between the convex portions 602 correspond to the second concave portion of the exemplary embodiment. Thus, the second convex portion and the second concave portion form a second convexo-concave structure of the exemplary embodiment. The same applies to the following exemplary embodiments.

In this exemplary embodiment, the second luminous intensity distribution converter 60 has the same dimension in a height and a width of the convex portion 602 and a gap between the adjacent convex portions 602 to provide the second convexo-concave structure having periodicity. When the second convexo-concave structure of the second luminous intensity distribution converter 60 is formed in dimensions so as to be non-diffractive, even when the radiation light emitted from the organic compound layer 20 is white light, white emission can be efficiently obtained without dispersion.

In order that the second convexo-concave structure of the second luminous intensity distribution converter 60 provides the non-diffractive and periodic structure in the same manner as above, the height and the width of the convex portion 602 and the gap between the adjacent convex portions 602 need to be sufficiently larger than the wavelength in the visible light region, usually need to be 1 μm or more, preferably 5 μm or more, which is equal to or longer than the optical coherence length, and further preferably 20 μm or more. When the plurality of convex portions 602 are formed with a pitch therebetween that is equal to or more than the optical coherence length, the non-diffractive radiation light is obtainable. In order to efficiently extract the light from the light-transmissive substrate 50, the height and the width of the convex portion 602 and the gap between the convex portions are preferably 1 mm or less.

Examples of the material for forming the second luminous intensity distribution converter 60 include a glass material and a polymer material. Examples of the glass material include soda-lime glass, barium/strontium-containing glass, lead glass, aluminosilicate glass, borosilicate glass, barium borosilicate glass and quartz. For the polymer material, materials such as polycarbonate resins, acryl resins, polyethylene terephthalate resins, polyether sulfide resins, polysulfone resins and cycloolefin resins can be used. A refractive index n_{c2} of the second luminous intensity distribution converter 60 is preferably equal to the refractive index of the light-transmissive substrate 50. When the refractive index n_{c2} of the second luminous intensity distribution converter 60 is equal to the refractive index n₂ of the light-transmissive substrate 50, loss in light reflection generated at the interface between the light-transmissive substrate 50 and the second luminous intensity distribution converter 60 is reducible. A refractive index of a glass substrate used as the light-transmissive substrate is usually 1.5. Refractive indexes of other materials used as the light-transmissive substrate for the organic EL device range from a relatively low refractive index of approximately 1.4 to a relatively high refractive index of approximately 1.65. Since the refractive index of the second luminous intensity distribution converter 60 is preferably equal to that of the light-transmissive substrate 50, a difference between the refractive indexes of full spectrum ranging from 380 nm to 280 nm is preferably in a range ±0.3.

A material for forming the convex portion 602 of the second luminous intensity distribution converter 60 may be different from that for forming the base 601. The second luminous intensity distribution converter 60 may be provided by adhering the convex portion 602 to the base 601. The convex portion 602 may be formed by processing a plate member formed of the above material having a thickness that is equal to or more than the target thicknesses of the base 601 and the convex portion 602.

### Manufacturing Method of Organic EL Device

### Formation of First Luminous Intensity Distribution Converter

Firstly, the low refractive layer 42 is formed.

A low-refractive-index material for forming the low refractive layer 42 is uniformly coated on the light-transmissive substrate 50. Herein, the low-refractive-index material is a resist. Next, a mold having a convexo-concave shape corresponding to a pattern in which a plurality of the convexo-concave units 41A according to the first exemplary embodiment is provided is heated. The heated mold is pressed onto the low-refractive-index material to soften the material and to transfer the convexo-concave shape (thermal imprinting). Then, the mold and the low-refractive-index material are subjected to exposure and curing by ultraviolet rays and heated at 180 degrees C. for 30 minutes, and then, cooled approximately to a room temperature. When the mold is detached, the low refractive layer 42 is formed on the light-transmissive substrate 50.

Next, the high refractive layer 41 is formed.

A high-refractive-index material for forming the high refractive layer 41 is uniformly coated on the low refractive layer 42 on the light-transmissive substrate 50. Here, an ink composition provided by uniformly dispersing metal oxide particles in a resin binder is coated by spin coating. By adjusting the number of coating, the high-refractive-index material is filled in the concave portions of the convexo-concave shape of the low refractive layer 42 and the thickness of the high refractive layer 41 (corresponding to the above distance d₁) is set to be equal to or more than the optical coherence length. Subsequently, the ink composition is dried and solidified to form the high refractive layer 41.

Since the ink composition is coated on the convexo-concave shape molded on the low refractive layer 42 to form the high attractive layer 41, the high refractive layer 41 has a shape corresponding to the convexo-concave units 41A. By further coating a high-refractive-index material to provide a flat layer, a surface of the high refractive layer 41 on which the transparent electrode is formed can have a high refractive index and a surface roughness Ra of 2 nm or less.

Thus, the first luminous intensity distribution converter 40 is formed.

### Formation of Second Luminous Intensity Distribution Converter

The second luminous intensity distribution converter 60 is formed on a surface (i.e., a light-extraction surface) opposed to the surface of the light-transmissive substrate 50 on which the first luminous intensity distribution converter 40 is formed. The material for forming the second luminous intensity distribution converter 60 is coated on the light-transmissive substrate 50. Here, a thermoplastic resin material is used. Next, a mold having a convexo-concave shape corresponding to a pattern of the convexo-concave structure according to the first exemplary embodiment is heated. The heated mold is pressed onto the thermoplastic resin material to soften the material and to transfer the convexo-concave shape (thermal imprinting). Then, the mold and the thermoplastic resin material are cooled approximately to the room temperature. When the mold is detached, the second luminous intensity distribution converter 60 is formed on the light-extraction surface of the light-transmissive substrate 50.

### Formation of Organic Emitting Layer and Electrode

After the first luminous intencity distribution converter 40 and the second luminous intensity distribution converter 60 are formed, the second electrode 30, the organic compound layer 20 and the first electrode 10 are sequentially laminated on the high refractive layer 41. The first electrode 10 and the second electrode 30 may be formed by a method such as vacuum deposition and sputtering. The organic compound lever 20 may be formed by a method including dry film-forming such as vacuum deposition, sputtering, plasma deposition and ion plating, and wet film-forming such as spin coating, dipping, flow coating and ink jet.

Thus, the organic EL device 1 including the first luminous intensity distribution converter 40 having the plurality of convexo-concave units 41A can be obtained.

### Advantages of First Exemplary Embodiment

According to the above-described first exemplary embodiment the following advantages can be obtained.

The first luminous intensity distribution converter 40 of the organic EL device 1 converts the luminous intensity distribution such that the ratio of the light in the substrate mode relative to the total light flux of the radiation light in the light-transmissive substrate 50 is 20% or more. After the first luminous intensity distribution converter 40 converts the luminous intensity distribution, the second luminous intensity distribution converter 60 converts the angle of the light in the substrate mode having entered the light-transmissive substrate 50 toward the normal of the surface of the light-transmissive substrate 50.

With thus arranged organic EL device 1, after the first luminous intensity distribution converter 40 increases the ratio of the light components in the substrate mode relative to the total light flux in the light-transmissive substrate 50 to 20% or more, and the increased light in the substrate mode can be converted by the second luminous intensity distribution converter 60 toward the normal of the light-transmissive substrate 50. In other words, the organic EL device 1 initially guides the light components conventionally confined in the device into the light-transmissive substrate 50 as the light in the substrate mode, and extracts the light in the substrate mode to the outside of the device.

Consequently, the organic EL device 1 can extract more light components confined in the device to the outside of the device, thereby improving the external quantum efficiency.

According to the organic EL device 1, in the first luminous intensity distribution converter 40, the high refractive layer 41 and the low refractive layer 42 are laminated in this sequence on the second electrode 30, and the convexo-concave units 41A are formed between the high refractive layer 41 and the low refractive layer 42. Accordingly, the light incident on the high refractive layer 41 at an angle that is equal to or more than the critical angle does not totally reflect at the interface between the high refractive layer 41 and the low refractive layer 42, but is transmitted to the low refractive layer 42 to enter the light-transmissive substrate 50, Thus, according to the organic EL device 1, the light components in the substrate mode in the light-transmissive substrate 50 can be increased.

Moreover, according to the organic EL device 1, since the high refractive layer 41 having a film thickness equal to or more than the optical coherence length is provided between the second electrode 30 and the light-transmissive substrate 50, a ratio of light to be bonded to the surface plasmon mode relative to the radiation light from the emitting layer of the organic compound layer 20 is decreased while a ratio of light to be bonded to the thin film mode is increased. As a result, among the light in the thin film mode, the light incident on the high refractive layer 41 at the angle that is equal to or more than the critical angle does not totally reflect at the interface between the second electrode 30 and the high refractive layer 41, but is transmitted to the low refractive layer 42. In consequence, the light is extracted to the outside of the organic EL device 1 via the light-transmissive substrate 50 and the second luminous intensity distribution converter 60.

Thus, the light-extraction efficiency of the radiation light generated in the emitting layer of the organic compound layer 20 can be improved.

According to the organic EL device 1, since the height d₂ and the width d₃ of the convex portion 411 and the gap d₄ between the convex portions are sufficiently larger than the wavelength in the visible light region, the white light is not likely to be dispersed unlike a diffraction grating having a periodicity and a protrusion height of approximately submicron order.

Accordingly, the organic EL device 1 can provide a favorable white emission with small diffractiveness and is suitable to a light source of an illumination unit.

### Second Exemplary Embodiment

Next, a second exemplary embodiment of the invention will be described below with reference to the attached drawings.

### Organic Electroluminescence Device

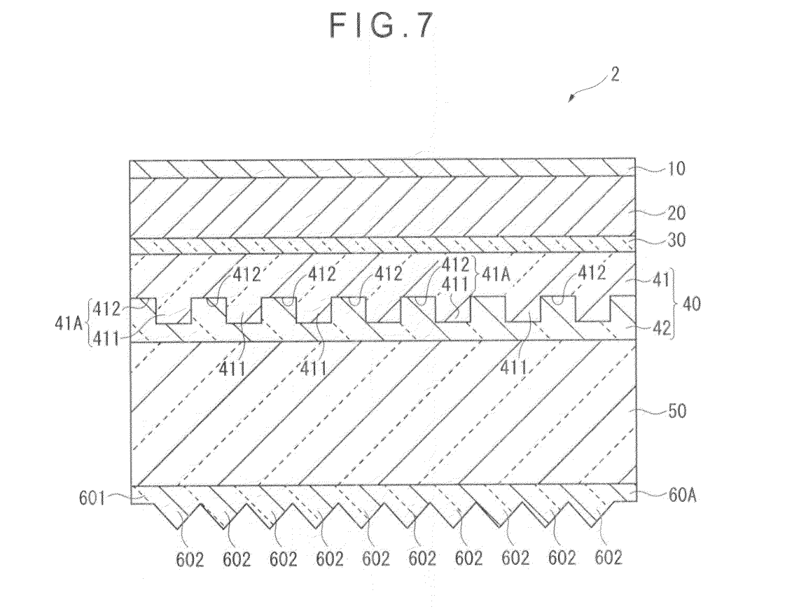

FIG. 7 is a schematic cross-sectional view in a thickness direction of a substrate of an organic EL device 2 according to the second exemplary embodiment.

The organic EL device 2 is different from the organic EL device 1 according to the first exemplary embodiment in the shape of the second luminous intensify distribution converter. The laminate structures of other parts in the second EL device 2 is the same as those in the organic EL device 1 according to the first exemplary embodiment. In the description of the second exemplary embodiment, the same components as those in the first exemplary embodiment are denoted by the same reference signs and names to simplify or omit an explanation of the components. In the second exemplary embodiment, the same materials and compounds as described in the first exemplary embodiment are usable.

The second luminous intensity distribution converter 60A of the organic EL device 2 includes a convex portion 603 having a triangular cross section projecting in the light-extraction direction from the base 601 as shown in FIGS. 6B and 7. As shown in FIG. 6B, a plurality of the convex portion 603 are formed in stripes.

In this exemplary embodiment, a second luminous intensity distribution converter 60A has the same dimension in a height and a width of the convex portion 603 and a gap between the adjacent convex portions 603, and has the second convexo-concave structure having periodicity. When the convexo-concave structure of the second luminous intensity distribution converter 60A is formed in dimensions so as to be non-diffractive, even when the radiation light emitted from the organic compound layer 20 is white light, white emission can be efficiently obtained without dispersion.

In order that the convexo-concave structure of the second luminous intensity distribution converter 60A provides a non-diffractive and periodic structure, the height and the width of the convex portion 603 and a distance between apexes of the cross-sectional triangles of the convex portions 603 need to be sufficiently larger than the wavelength in the visible light region, usually needs to be 1 μm or more, preferably 5 μm or more and further preferably 20 μm or more. In order to efficiently extract the light from the light-transmissive substrate 50, the height and the width of the convex portion 603 and the gap between the convex portions are preferably 1 mm or less.

### Advantages of Second Exemplary Embodiment

According to the above-described second exemplary embodiment, the following advantages can be obtained.

Since the organic EL device 2 also includes the first luminous intensity distribution converter 40 of the organic EL device 1 in the first exemplary embodiment, the organic EL device 2 converts the luminous intensity distribution such that the ratio of light in the substrate mode relative to the total light flux of the radiation light in the light-transmissive substrate 50 accounts for 20% or more.

After the first luminous intensity distribution converter 40 converts luminous intensity distribution, the second luminous intensity distribution converter 60A also converts the angle of the light in the substrate mode having entered the light-transmissive substrate 50 toward the normal of the surface of the light-transmissive substrate 50.

Consequently, the organic EL device 2 can extract more light components confined in the device to the outside of the device, thereby improving the external quantum efficiency.

### Third Exemplary Embodiment

Next, a third exemplary embodiment of the invention will be described below with reference to the attached drawings.

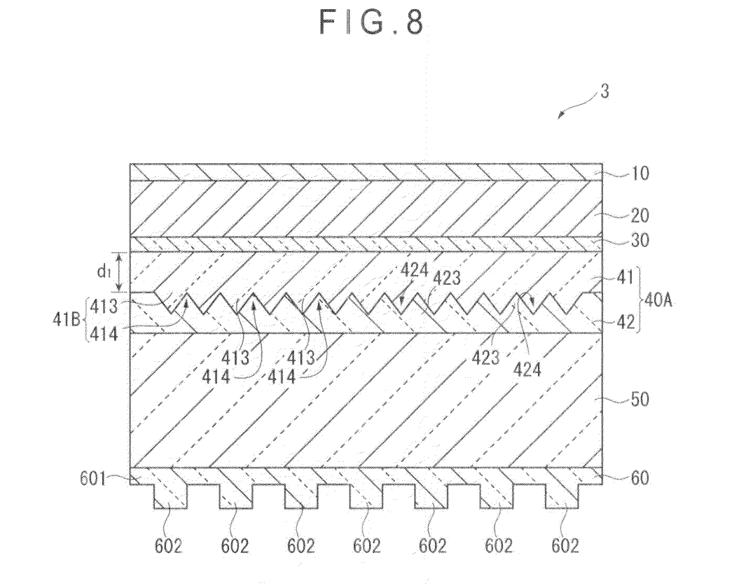

FIG. 8 is a schematic cross-sectional view in a thickness direction of a substrate of an organic EL device 3 according to a third exemplary embodiment.

The organic EL device 3 is different from the organic EL device 1 according to the first exemplary embodiment in the shape of the first luminous intensity distribution converter. The laminate structures of other parts in the second EL device 3 is the same as those in the organic EL device 1 according to the first exemplary embodiment. In the description of the third exemplary embodiment, the same components as those in the first exemplary embodiment are denoted by the same reference signs and names to simplify or omit an explanation of the components. In the third exemplary embodiment, the same materials and compounds as described in the first exemplary embodiment are usable.

The first luminous intensity distribution converter 40A of the organic EL device 3 includes a convex portion 413 having a triangular cross section projecting in the light-extraction direction from the high refractive layer 41 as shown in FIG. 8. Focusing on the high refractive layer 41, the convex portions 413 are formed in stripes as shown in FIG. 6B. A recess between the adjacent convex portions 413 is defined as a concave portion 414, The convex portion 413 and the concave portion 414 define a convexo-concave unit 41B. Since the low refractive layer 42 is formed to cover surfaces of the convex portions 413 formed in stripes, the low refractive layer 42 also includes a convex portion 423 having a triangular cross section and a concave portion 424 in a form of a recess between the adjacent convex portions 423.

In the first luminous intensity distribution converter 40A, a distance d₁ from the interface between the high refractive layer 41 and the second electrode 30 to the interface between the high refractive layer 41 and the low refractive layer 42 is equal to or longer than the optical coherence length. In the convex portion 413 having a triangular cross section, a dimension of a base line is preferably in a range of 2 μm to 10 mm and a height is preferably in a range of 2 μm to 10 mm. In the convex portion 413 having a triangular cross section, an angle formed by a hypotenuse and the base line is preferably larger than 0 degree and less than 45 degrees, more preferably larger than 0 degree and less than 25 degrees.

### Advantages of Third Exemplary Embodiment

According to the above-described third exemplary embodiment, the following advantages can be obtained.

The first luminous intensity distribution converter 40A of the organic EL device 3 can also convert the luminous intensity distribution such that the ratio of light in the substrate mode relative to the total light flux of the radiation light in the light-transmissive substrate 50 accounts for 20% or more.

After the first luminous intensity distribution converter 40A converts luminous intensity distribution, the second luminous intensity distribution converter 60 converts the angle of the light in the substrate mode having entered the light-transmissive substrate 50 toward the normal of the surface of the light-transmissive substrate 50.

Consequently, the organic EL device 3 can extract more light components confined in the device to the outside of the device, thereby improving the external quantum efficiency.

### Fourth Exemplary Embodiment

Next, a fourth exemplary embodiment of the invention will be described below with reference to the attached drawings.

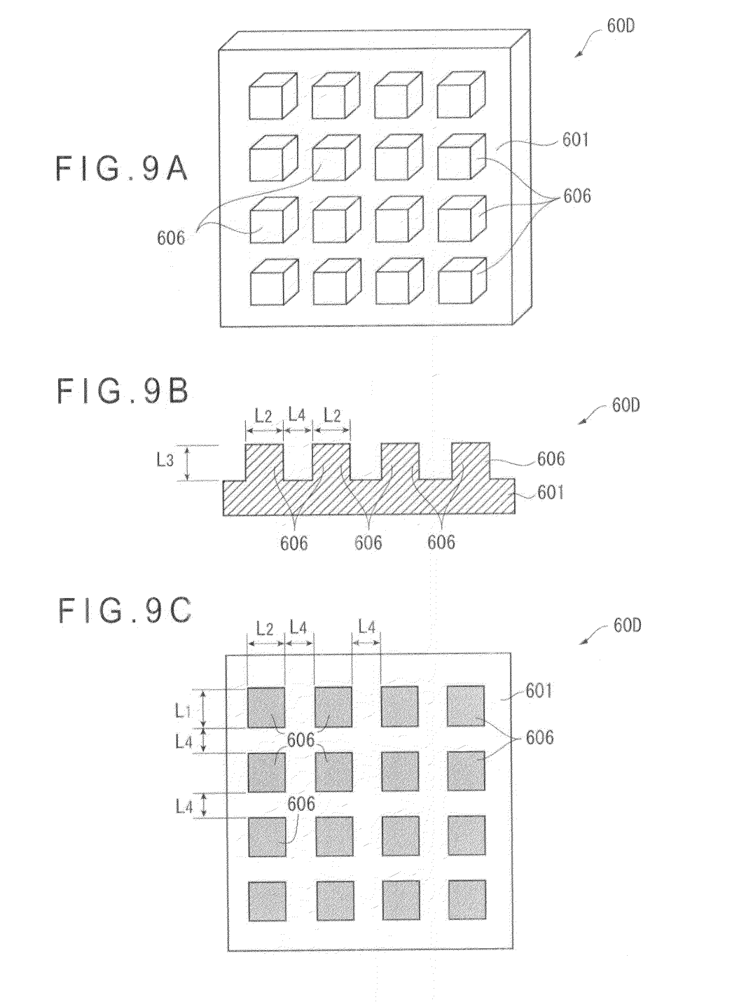

FIGS. 9A, 9B, and 9C are illustrations for showing a second luminous intensity distribution converter 60D of an organic EL device according to the fourth exemplary embodiment. FIG. 9A is a perspective view of the second luminous intensity distribution converter 60D. FIG. 9B is a cross-sectional view of the second luminous intensity distribution converter 60D. FIG. 9C is a plan view of the second luminous intensity distribution converter 60D.

In the organic EL device according to the fourth exemplary embodiment, the structures other than the second luminous intensity distribution converter 60D are the same as those in the organic EL device 1 according to the first exemplary embodiment. In the description of the fourth exemplary embodiment, the same components as those in the first exemplary embodiment are denoted by the same reference signs and names to simplify or omit an explanation of the components. In the fourth exemplary embodiment, the same materials and compounds as described in the first exemplary embodiment are usable.

As shown in FIG. 9A, the second luminous intensity distribution converter 60D includes a plurality of rectangular-parallelepiped convex portions 606 on the base 601. As shown in FIGS. 9A and 9C, the convex portions 606 are formed in a grating arrangement. A concave portion is defined between the convex portions 606.

As shown in FIGS. 9B and 9C, dimensions of the convex portion 606 are defined as a longitudinal dimension L₁, a lateral dimension L₂, a height L₃, and a gap L₄ of the adjacent convex portions 606.

The longitudinal dimension L₄ is preferably in a range of 3 μm to 10 mm. With this dimensional range, the dimensions of the convex portion 606 become equal to or more the optical coherence length, so that non-diffractive light can be obtained.

The lateral dimension L₂ is preferably in a range of 3 μm to 10 mm.

The gap L₄ is more than zero.

The height L₃ preferably satisfies at least one of the following two formulae (4-1) and (4-2). In the formulae (4-1) and (4-2), a unit for each of L₁, and L₂ and L₃ is μm (micrometer).

3>L₃/L₁>0.5 (4-1)

3>L₃/L₂>0.5 (4-2)

By defining the dimensions of the convex portion 606 so as to satisfy at least one of the formulae (4-1) and (4-2), decrease in an aperture ratio can be inhibited. As a result, decrease in a luminous efficiency of the organic EL device can be inhibited.

L₁, L₂ and L₄ preferably satisfy relationships of the formulae (4-5) and (4-4). In the formulae (4-5) and (4-4), a unit for each of L₁, L₂ and L₄ is μm (micrometer).

L₁+L₄>3 μm (4-3)

L₂+L₄>3 μm (4-4)

It is preferable to satisfy the relationships of the formulae (4-3) and (4-4), since a pitch between the convex portions 606 becomes equal to or more than the optical coherence length.

In the organic EL device according to the fourth exemplary embodiment, the second luminous intensity distribution converter 60D converts the angle of the light in the substrate mode having entered the light-transmissive substrate 50 toward the normal of the surface of the light-transmissive substrate 50. Accordingly, the organic EL device can extract more light components confined in the device to the outside of the device, thereby improving the external quantum efficiency.

### Fifth Exemplary Embodiment

Next, a fifth exemplary embodiment of the invention will be described below with reference to the attached drawings.

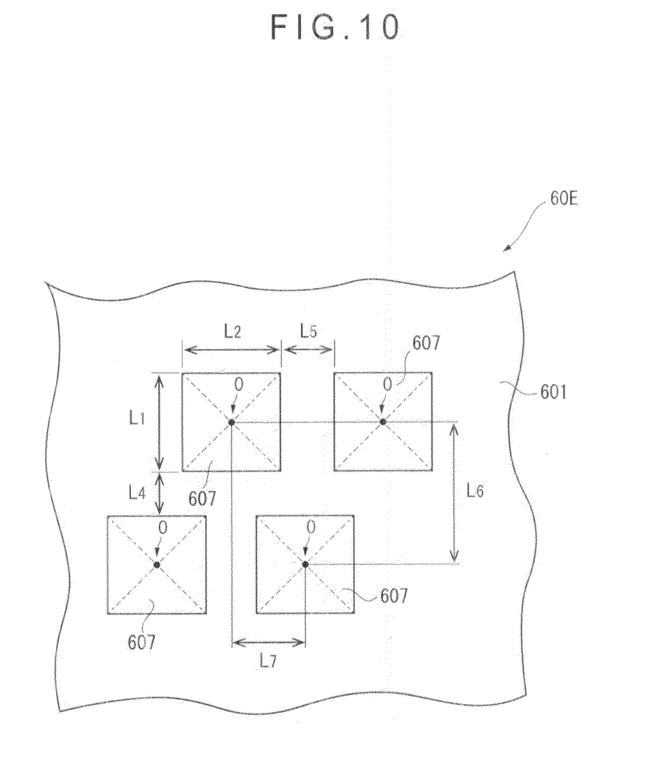

FIG. 10 is an illustration for showing a second luminous intensity distribution converter 60E of an organic EL device according to the fifth exemplary embodiment. FIG. 10 is a plan view of the second luminous intensity distribution converter 60E.

In the organic EL device according to the fifth exemplary embodiment, the structures other than the second luminous intensity distribution converter 60E are the same as those in the organic EL device 1 according to the first exemplary embodiment. In the description of the fifth exemplary embodiment, the same components as those in the first exemplary embodiment are denoted by the same reference signs and names to simplify or omit an explanation of the components. In the fifth exemplary embodiment, the same materials and compounds as described in the first exemplary embodiment are usable.

Although the second luminous intensity distribution converter 60E is the same as the second luminous intensity distribution converter 60D of the fourth exemplary embodiment in having a plurality of rectangular-parallelepiped convex portions, the second luminous intensity distribution converter 60E is different from the second luminous intensity distribution converter 60D in an arrangement of the convex portions. Specifically, as shown in FIG. 10, although dimensions of a convex portion 607 of the second luminous intensity distribution converter 60E are the same as those of the convex portion 606, the convex portions 607 are not formed in a grating arrangement on the base 601 but are misaligned from each other A concave portion between the convex portions 607 correspond to the second concave portion of the exemplary embodiment.

The convex portion 607 of the second luminous intensity distribution converter 60E is defined by the longitudinal dimension L₁, the lateral dimension L₂ and the height L₃ as shown in FIG. 10. In FIG. 10, a gap between the longitudinally adjacent convex portions 607 is defined as L₄ and a gap between the laterally adjacent convex portions 607 is defined as L₃. In a plan view of the convex portion 607 as shown in FIG. 10, when the center (intersection of diagonals of a quadrangle) of the convex portion 607 is denoted as O, a gap between the centers O of the longitudinally adjacent convex portions 607 is defined as L₆ in the longitudinal direction and as L7 in the lateral direction.

The longitudinal dimension L₁ is preferably in a range of 3 μm to 10 mm. With this dimensional range, the dimensions of the convex portion 607 become equal to or more the optical coherence length, so that non-diffractive light can be obtained.

The lateral dimension L₂ is preferably in a range of 3 μm to 10 mm.

The gap L₄ and L₃ are more than zero.

The height L₃ preferably satisfies at least one of the following two formulae (5-1) and (5-2). In the formulae (5-1) and (5-2), a unit for each of L₁, L₂ and L₃ is μm (micrometer).

3>L₃/L₁>0.5 (5-1)

3>L₃/L₂>0.5 (5-2)

By defining the dimensions of the convex portion 607 so as to satisfy at least one of the formulae (5-1) and (5-2), decrease in an aperture ratio can be inhibited. As a result, decrease in a luminous efficiency of the organic EL device can be inhibited.

L₆ preferably satisfies the formula (5-3). In the formula (5-3), a unit for each of L₁, L₄ and L₆ is μm (micrometer).

L₁+L₄>L₆≧0 μm (5-3)

L₇ preferably satisfies the formula (5-4). In the formula (5-4), a unit for each of L_{2, L}₅ and L₇ is μm (micrometer),

L₂+L₅>L₇≧0 μm (5-4)

By defining the dimensions of the convex portion 607 so as to satisfy at least one of the formulae (5-3) and (5-4), the convex portions 607 of the second luminous intensify distribution converter 60E can be misaligned instead of the grating arrangement of the convex portions 606 of the second luminous intensity distribution converter 60D, so that uniform emission can be obtained.

L₁, L₂ and L₄ preferably satisfy relationships of the formulae (5-5) and (5-6). An unit for each of L₁, L₂ and L₄ is μm (micrometer).

L₁+L₄>3 μm (5-5)

L₂+L₄3 μm (5-6)

Accordingly, a pitch between the convex portions 607 becomes equal to or more than the optical coherence length.

According to the organic EL device according to the fifth exemplary embodiment, the second luminous intensity distribution converter 60E converts the angle of the light in the substrate mode which enters the light-transmissive substrate 50 toward the normal of the surface of the light-transmissive substrate 50. Accordingly, the organic EL device can extract more light components confined in the device to the outside of the device, thereby improving the external quantum efficiency.

### Sixth Exemplary Embodiment

Next, a sixth exemplary embodiment of the invention will be described below with reference to the attached drawings.

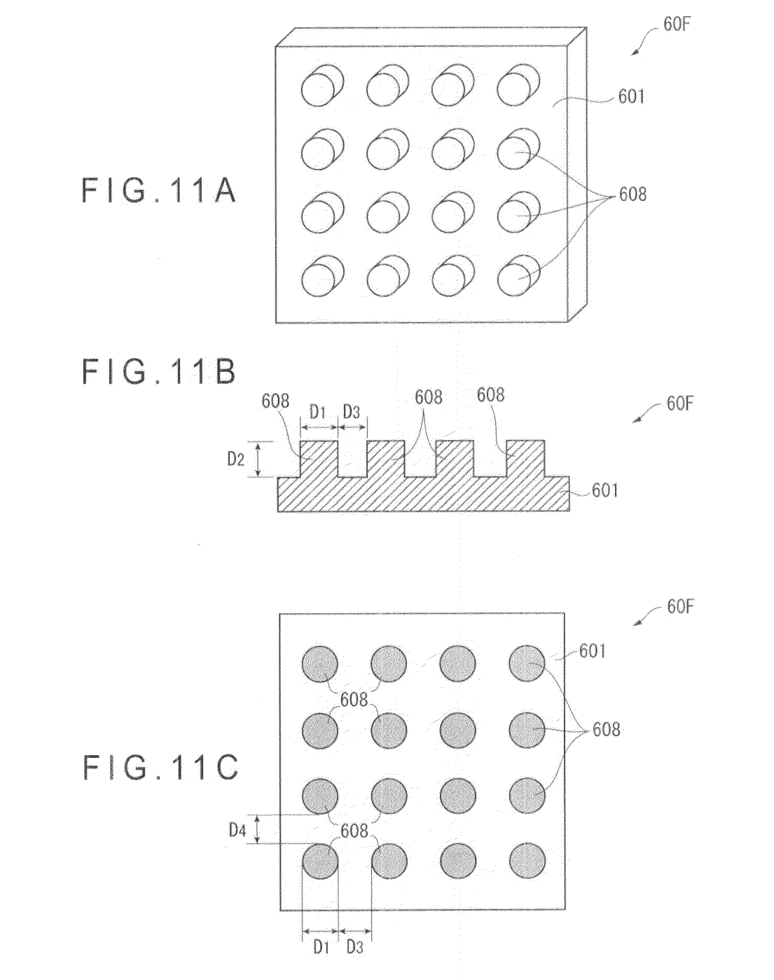

FIGS. 11A, 11B and 11C are illustrations for showing a second luminous intensity distribution converter 60F of an organic EL device according to the sixth exemplary embodiment. FIG. 11A is a perspective view of the second luminous intensity distribution converter 60F. FIG. 11B is a cross-sectional view of the second luminous intensity distribution converter 60F. FIG. 11C is a plan view of the second luminous intensity distribution converter 60F.

In the organic EL device according to the sixth exemplary embodiment, the structures other than the second luminous intensity distribution converter 60F are the same as those in the organic EL device 1 according to the first exemplary embodiment. In the description of the sixth exemplary embodiment, the same components as those in the first exemplary embodiment are denoted by the same reference signs and names to simplify or omit an explanation of the components. In the sixth exemplary embodiment, the same materials and compounds as described in the first exemplary embodiment are usable.

As shown in FIG. 11A, the second luminous intensity distribution converter 60F includes a plurality of columnar convex portions 608 on the base 601. As shown in FIGS. 11A and 11C, the convex portions 608 are formed in a grating arrangement. A concave portion between the convex portions 608 correspond to the second concave portion of the exemplary embodiment.

As shown in FIGS. 11B and 11C, dimensions of the convex portion 608 are defined as a diameter D₁ and a height of D₂ of a column. As shown in FIG. 11C, a gap between the laterally adjacent convex portions 608 is denoted as D₃ and a gap between the longitudinally adjacent convex portions 608 is denoted as D₄.

The diameter D₁ is preferably in a range of 2 μm to 10 mm.

The height D₂ is preferably in a range of 2 μm to 10 mm.

The gap D₃ is preferably in a range of 2 μm to 10 mm. The diameter D₁ and height D₂ preferably satisfy a relationship of the formula (6-1). In the formula (6-1), a unit for each of D₁ and D₂ is μm (micrometer).

3>D₂/D>0.5 (6-1)

The gap D₄ is preferably in a range of 2 μm to 10 mm.

A pitch between the adjacent convex portions 608 preferably becomes equal to or more than the optical coherence length.

According to the organic EL device according to the sixth exemplary embodiment, the second luminous intensity distribution converter 60F converts the angle of the light in the substrate mode which enters the light-transmissive substrate 50 toward the normal of the surface of the light-transmissive substrate 50. Accordingly, the organic EL device can extract more light components confined in the device to the outside of the device, thereby improving the external quantum efficiency.

### Seventh Exemplary Embodiment

Next, a seventh exemplary embodiment of the invention will be described below with reference to the attached drawings.

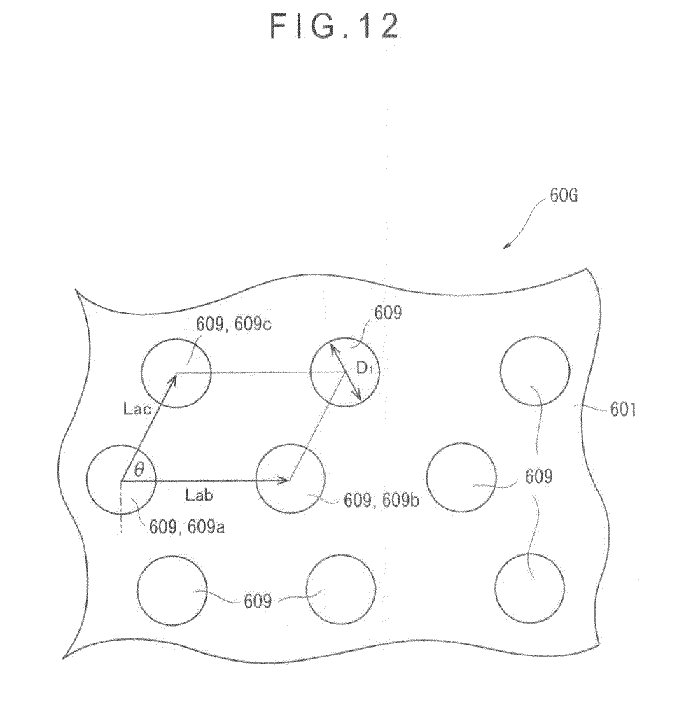

FIG. 12 is an illustration for showing a second luminous intensity distribution converter 60G of an organic EL device according to the seventh exemplary embodiment. FIG. 12 is a plan view of the second luminous intensity distribution converter 60G.

In the organic EL device according to the seventh exemplary embodiment, the structures other than the second luminous intensity distribution converter 60G are the same as those in the organic EL device 1 according to the first exemplary embodiment. In the description of the seventh exemplary embodiment, the same components as those in the first exemplary embodiment are denoted by the same reference signs and names to simplify or omit an explanation of the components. In the seventh exemplary embodiment, the same materials and compounds as described in the first exemplary embodiment are usable.

Although the second luminous intensity distribution converter 60G is the same as the second luminous intensity distribution converter 60F of the sixth exemplary embodiment in having a plurality of columnar convex portions, the second luminous intensity distribution converter 60G is different from the second luminous intensity distribution converter 60F in an arrangement of the convex portions. Specifically, as shown in FIG. 12, although dimensions of a convex portion 609 of the second luminous intensity distribution converter 60G is the same as those of the convex portion 608, the convex portions 609 are not formed in a grating arrangement on the base 601 but are misaligned from each other. A concave portion between the convex portions 609 correspond to the second concave portion of the exemplary embodiment.

The convex portion 609 is defined as the diameter D₁ and the height D₂ of the column in the same manner as the convex portion 608. As shown in FIG. 12, to what extent the convex portions 609 are misaligned from each other is defined by an angle θ defined by a line segment L_{ab}, which connects the center of a convex portion 609a and the center of a convex portion 609b laterally adjacent to the convex portion 609a, and a line segment L_{ac} between the center of the convex portion 609a and the center of a convex portion 609c diagonally adjacent to the convex portion 609a.

The angle θ is set in a range of 0 degree<θ<180 degrees.

A length of each of the line segments L_{ab} and L_{ac} satisfies L_{ab}>D₁ and L_{ac}>D₁, and is preferably equal to or more than the optical coherence length. In other words, a pitch between the convex portions 609a is preferably equal to or more than the optical coherence length.

The diameter D₁ and height D₂ preferably satisfy a relationship of the formula (7-1). In the formula (7-1), a unit for each of D₁ and D₂ is μm (micrometer).

3>D₂/D₁>0.5 (7-1)

According to the organic EL device according to the seventh exemplary embodiment, the second luminous intensity distribution converter 60G converts the angle of the light in the substrate mode which enters the light-transmissive substrate 50 toward the normal of the surface of the light-transmissive substrate 50. Accordingly, the organic EL device can extract more light components confined in the device to the outside of the device, thereby improving the external quantum efficiency.

### Modifications of Exemplary Embodiment(s)

It should be noted that the invention is not limited to the above exemplary embodiments but may include the following modifications as long as such modifications are compatible with an object of the invention.

In addition to the patterns described in the above exemplary embodiments, the second luminous intensity distribution converter 60 may be provided by a second luminous intensity distribution converter 60B including a convex portion 604 having a semi-circular cross section as shown in FIG. 6C, or alternatively, may be provided by a second luminous intensity distribution converter 60C including a convex portion 605 having a semi-circular cross section on a rectangular base as shown in FIG. 6D.

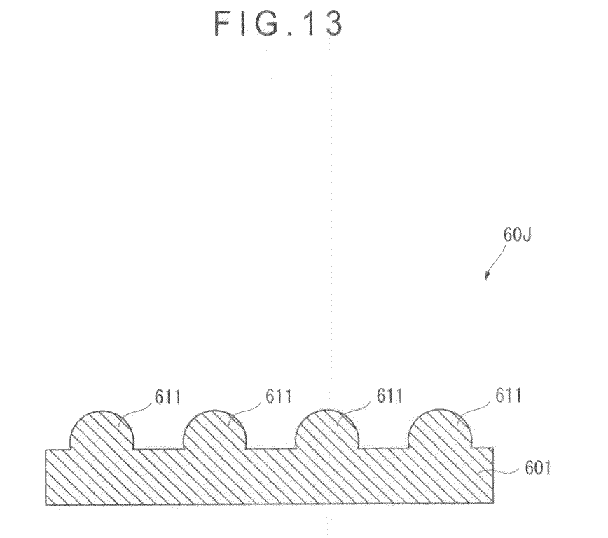

Alternatively, unlike the second luminous intensity distribution converter 60F including the columnar convex portions 608 formed in a grating arrangement, the second luminous intensity distribution converter 60 may be provided by a second luminous intensity distribution converter 60J including hemispheric convex portions 611 formed in a grating arrangement as shown in FIG. 13. In this arrangement, a diameter of the hemisphere is preferably in a range of 3 μm to 10 mm.

The second convex portion (e.g., convex portion 604) may be formed in a spindle shaped in a triangular pyramid, a cone and the like.

Further, a hemispheric lens, a columnar lens and a cylindrical lens are also usable.

The second luminous intensity distribution converter is not limited to ones according to the above exemplary embodiments as long as the second luminous intensity distribution converter can convert radiation distribution of the light in the substrate mode which is confined in the light-transmissive substrate 50 into radiation distribution of the light in the normal direction of the surface of the light-transmissive substrate 50.

In the first and second exemplary embodiments, the convex portions 411 of the convexo-concave unit 41A project from the second electrode 30 toward the light-transmissive substrate 50 in a substantially columnar shape and the convex portions 411 have approximately rectangular cross section as shown in FIG. 4. However, the convex portions 411 may have other shapes.

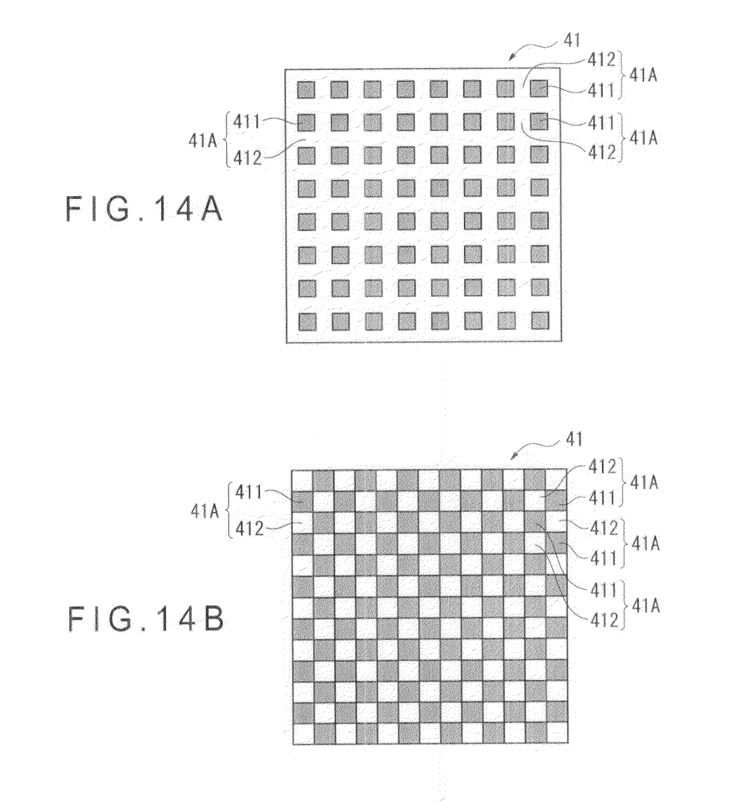

FIGS. 14A and 14B are plan views showing a part of the high refractive layer 41 from the side of the light-transmissive substrate 50 in the same manner as FIGS. 3A, 3B and 3C. As shown in FIGS. 14A and 14B, the convex portions 411 may be provided as quadrangular columns protruding in quadrangles in a plan view. The convex portions 411 may be arranged in a grating pattern as shown in FIG. 14A, or may be arranged in a close-pack structure as shown in FIG. 14B. Alternatively, the convex portions 411 may be arranged in a houndstooth check pattern (not shown).

The gap, width and height of the convex portions 411 nary not be the same among all of the convexo-concave units 41A. Further, the convex portions 411 may be arranged not regularly but in random.

Further, the above dimensional relationship of the height d₂, the width d₃ and the gap d₄ for defining the convexo-concave unit 41A may not be satisfied by all of the convexo-concave units 41A but it is sufficient that at least one of the convexo-concave units 41A satisfies the relationship.

Further, in the organic EL device 1 described in the first exemplary embodiment, the above dimensional relationship between the first luminous intensity distribution converter 40 and the convexo-concave unit 41A defined by the optical coherence length may be satisfied not in the cross section taken along IV-IV line in FIG. 3B but in a cross section taken along X-X line in FIG. 3B.

The first luminous intensity distribution converter 40 and the second luminous intensity distribution converter 60 are not limited to ones described in the above exemplary embodiments.

For instance, the first luminous intensity distribution converter 40 is formed by transferring a pattern corresponding to the shape of the plurality of convexo-concave units 41A to a film formed of a material forming the high refractive layer 41 and having a thickness equal to or more than the sum of the distance d₁ and the height d₂ to form a convexo-concave pattern. Subsequently, a solution of a material forming the low refractive layer 42 may be applied on the surface of the high refractive layer 41 on which the convexo-concave pattern is formed to form the low refractive layer 42, thereby forming the first luminous intensity distribution converter 40. In reverse, the convexo-concave pattern may be formed on a film formed of a material forming the low refractive layer 42 and a solution of a material forming the high refractive layer 41 may be applied thereon to provide the high refractive layer 41.

Alternatively, a convexo-concave pattern corresponding to the shape of the plurality of convexo-concave units 41A may be formed by applying a resin binder in which fine particles of titania or zirconia are dispersed on a base film of a material forming the high refractive layer 41 and having a thickness of more than the distance d₁. Subsequently, a solution of a material forming the low refractive layer 42 may be applied on the surface on which the convexo-concave pattern is formed to form the low refractive layer 42, thereby forming the first luminous intensity distribution converter 40. It should be noted that the high refractive layer 41 and the low refractive layer 42 may also be reversely formed. The refractive index nₚ of the dispersed particles satisfy a relationship of n_{H}≦nₚ.

The first luminous intensity distribution converter 40 thus formed and the light-transmissive substrate 50 are laminated by, for instance, adhering the first luminous intensity distribution converter 40 and the light-transmissive substrate 50 with an adhesive and the like of which refractive index is substantially equal to the refractive index of the material forming the low refractive layer 42.

Although the organic EL device is described as a bottom-emission device in the above exemplary embodiments, the organic EL device may not necessarily be limited thereto, for instance, the invention is applicable to a top-emission device.

### EXAMPLES

Next, the invention will be described in further detail by exemplifying Example(s). However, the invention is not limited by the description of Example(s).

In these Examples, an organic EL device was manufactured, a drive test was performed and an external quantum efficiency was measured while checking a luminous intensity distribution chart.

### 1. Manufacturing of Organic EL Device

### Example 1

### (1) Formation of First Luminous Intensity Distribution Converter

### (1-1) Formation of Low Refractive Layer

A resist material (NEX907: manufactured by NIPPON STEEL CHEMICAL CO., LTD.) dissolved in xylene was used as a coating liquid for forming the low refractive layer. Next, the coating liquid was applied on a glass substrate (light-transmissive substrate) of 25 mm×25 mm×0.7 mm thick (NA35: manufactured by Nippon Sheet Glass Co., Ltd,) and a refractive index of 1.50 (wavelength=550 nm) by spin coating. The coating was conducted while keeping rotation at 1000 rpm for 60 seconds.

Subsequently, the glass substrate was held on a hot plate of 180 degrees C. for 20 minutes to dry the coating liquid, thereby forming a resist film. The thickness of the resist film was 20 μm.

An ellipsometer manufactured by J.A. Woollam Co. was used for measuring the refractive index. The measured value of the refractive index was 1.50 (wavelength=550 nm). The following refractive indexes were similarly measured.

Next, a pattern in which a plurality of convexo-concave units were arranged (first luminous intensity distribution conversion pattern) was transferred to the above resist film by thermal imprinting. A mold having the first luminous intensity distribution conversion pattern formed on a silicon substrate of 20 mm×20 mm×0.7 mm thick by photolithography was used. The first luminous intensity distribution conversion pattern was a pattern shown in FIG. 14A in which convex portions formed in cubes of 3 μm long, 3 μm wide and 3 μm high were arranged with a 3-μm gap between the cubes in a grating arrangement (hereinafter, this pattern may occasionally be referred to as a grating).

The glass substrate and the mold were overlaid such that the resist film and the first luminous intensity distribution conversion pattern faced each other and were put on a stage of a thermal imprinting apparatus. The mold was pressed onto the resist film at a pressure of 2 MPa and the heating temperature was set such that the temperature of the resist film became 120 degrees C. The state was kept for three minutes in order to soften the resist film. Subsequently, the heating of the stage and the opposing plate was stopped and naturally cooled. When the temperature of the mold and the resist film returned to a room temperature, the pressure was released, the resist material was cured by exposure to ultraviolet rays, and the resist-film-formed substrate and the mold were extracted. The substrate and the mold were separated to obtain the resist film (i.e. a low refractive layer transferred with the first luminous intensity distribution conversion pattern on the glass substrate). When the resist film was observed by an atomic force microscope, it was found that concave portions in a form of cubic dents of 3 μm long, 3 μm wide and 3 μm deep were framed in a grating arrangement with a 3-μm gap from each other.

### (1-2) Formation of High Refractive Layer

A mixed material of titanium oxide particles and a resin was used as a high refractive material. Highly transparent particulated titanium oxide slurry manufactured by Tayca Corporation (titanium oxide particle diameter: 15 nm to 25 nm, solvent: propylene glycol monomethyl ether) was used as titanium oxide particles. A resist material (NEX907: manufactured by NIPPON STEEL CHEMICAL CO., LTD.) was used as the resin. An ink for forming a high refractive layer was prepared so that the solid mass ratio of the both became titanium oxide particle slurry:resist solution=5.0:5.0.

In order to measure a refractive index of the high refractive material film, the ink for forming the high refractive layer was applied on another glass substrate by spin coating. Subsequently, the ink was dried at 100 degrees C. to form a high refractive material film. The thickness of the high refractive material film was 1.8 μm. Further, the refractive index of the high refractive material film was 1.83 (wavelength=550 nm).

The ink for forming the high refractive layer was applied on the resist film (the low refractive layer), which had the first luminous intensity distribution conversion pattern on the light-transmissive substrate prepared by the thermal imprinting, by spin coating. The coating was conducted while keeping rotation at 1500 rpm for 60 seconds. Subsequently, the ink for forming the high refractive layer was further applied on the film three times. The film was held on a hot plate of 180 degrees C. for 20 minutes to dry the ink for forming the high refractive layer. After the high refractive layer was sufficiently dried, a flat surface of a polyethylene film coated with a peeling material was pressed onto the high refractive layer at a pressure of 2 MPa to flatten the high refractive layer. The film and the high refractive layer on the glass substrate were held on a hot plate of 180 degrees C. for 60 minutes to dry the ink for forming the high refractive layer, and then, the resist material was cured by exposure to ultraviolet rays. Subsequently, the polyethylene film was peeled to form a high refractive material film.

The glass substrate was cut along the thickness direction of the substrate. When the cross section was observed by an atomic force microscope, it was found that a first luminous intensity distribution converter in a grating pattern was formed by the lamination of the above resist film (low refractive layer) and the high refractive material film (high refractive layer) on the glass substrate. The dimensions of the high refractive layer, the low refractive layer and the convexo-concave unit of the first luminous intensity distribution converter described in the first exemplary embodiment were: the distance d₁=10 μm; the height d₂=3 μm; the width d₃=3 μm; and the gap d₄=3 μm.

### (2) Formation of Second Luminous Intensity Distribution Converter

Next, the second luminous intensity distribution converter was formed on a surface (i.e., a light-extraction surface) opposed to the surface of the glass substrate on which the first luminous intensity distribution converter was formed.

Specifically, firstly, an index-matching oil having a refractive index of 1.5 was partially coated on the light-extraction surface of the glass substrate. 4-mm diameter hemispheric lenses made of BK7 glass were adhered on the index-matching oil in a square grating arrangement.

### (3) Formation of Electrode and Organic Compound Layer

Next, an electrode and an organic compound layer were laminated on the glass substrate on which the first luminous intensity distribution converter and the second luminous intensity distribution converter were formed.

Firstly, IZO was evaporated on the high refractive layer of the first luminous intensity distribution converter to form a 110-nm thick IZO film, thereby providing a transparent electrode (second electrode).

A hole-injecting compound HI-1 was evaporated on the IZO film to form a 5-nm thick hole injecting layer.

A hole-transporting compound HT-1 was evaporated on the hole injecting layer to form a 145-nm thick first hole transporting layer.

A hole-transporting compound HT-2 was evaporated on the first hole transporting layer to form a 10-nm thick second hole transporting layer.

Further, a compound GH-1 (a host material) and a compound GD-1 (a fluorescent dopant material) were co-evaporated on the second hole transporting layer to form a 25-nm thick emitting layer. A concentration of the compound GD-1 in the emitting layer was 5 mass %. The maximum emission peak wavelength of the compound GD-1 was 520 nm.

An electron-transporting compound ET-1 was evaporated on the emitting layer to form a 5-nm thick first electron transporting layer.

Next, an electron-transporting compound ET-2 was evaporated on the first electron transporting layer to form a 30-nm thick second electron transporting layer.

Next, an electron-transporting compound ET-3 was evaporated on the second electron transporting layer to form a 5-nm thick second electron transporting layer.

LiF was evaporated on the third electron transporting layer at a film-forming speed of 0.1 angstrom/min to form a 1-nm thick LiF film as an electron injecting electrode (cathode).

A metal Al was evaporated on the LiF film to form an 80-nm thick metal cathode.

Thus, the organic EL device of Example 1 was prepared.

### Example 2

An organic EL device of Example 2 was prepared in the same manner as that of Example 1 except that the convexo-concave structure of the first luminous intensity distribution converter was provided by a plurality of convex portions having a triangular cross section of a 25-μm height and a 50-μm base line arranged adjacent to each other in stripes (triangular-wave cross section) (see FIGS. 6B and 7). It should be noted that the pattern of the first luminous intensity distribution converter used in the organic EL device of Example 2 is occasionally referred to as a prism sheet pattern hereinafter.

### Comparative 1

An organic EL device was manufactured in the same manner as in the Example 1 except that the first luminous intensity distribution converter was not formed. In other words, the second luminous intensity distribution converter was formed on the light-transmissive substrate and the electrode and the organic compound layer were directly formed on the other surface of the light-transmissive substrate.

### References 1 to 3

For comparison with the luminous intensity distribution charts of the organic EL devices in Examples 1 and 2 and Comparative E organic EL devices of References 1 to 3 were prepared for reference.

The organic EL device of Reference 1 was manufactured in the same manner as in the Example 1 except that the first and second luminous intensity distribution converters were not formed in Example 1. In other words, the electrode and the organic compound layer were directly formed on the light-transmissive substrate. The organic EL device of Reference 2 was manufactured in the same manner as in the Example 1 except that the second luminous intensity distribution converter was not formed in Example 1.

The organic EL device of Reference 3 was manufactured in the same manner as in the Example 1 except that the second luminous intensity distribution converter was not formed in Example 2.

The organic EL devices of Examples 1 and 2, Comparative 1 and References 1 to 3 are the same in the layer structure from the transparent electrode made of IZO to the metal cathode made of Al, but are different in the laminate structure beyond the transparent electrode to the light-transmissive substrate (to the light-extraction side).

### (2) Drive Test

In the drive test of the organic EL device, voltage was applied to the organic EL device so that a current density became 10 mA/cm², and EL emission spectrum at that time was measured by a spectro radiance meter (CS-1000: manufactured by Konica Minolta Sensing, Inc.).

An external quantum efficiency was calculated based on spectral radiance spectrum (wavelength of 380 nm to 780 nm) obtained from measurement of radiation light at all emission angles.

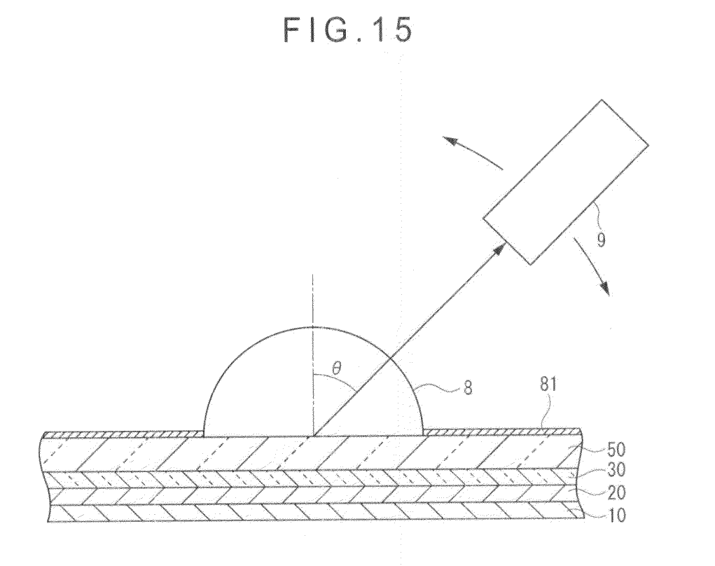

FIG. 15 is a schematic view for showing an evaluation method of luminous intensity distribution of light emitted from the manufactured organic EL device.

Radiation light emitted from the light-extraction surface of the manufactured organic EL device was measured using a luminous intensity distribution measuring instrument manufactured by Asahi Spectra Co., Ltd. while changing an angle of a light receiver 9. As shown in FIG. 15, provided that the normal direction of the light-transmissive substrate 50 was defined as θ=0 degree and a measurement position of the light receiver 9 was displaced every 5 degrees in a range of −90 degrees≦θ≦90 degrees, EL emission spectrum at every angle was measured.

FIG. 15 is a schematic view of a measurement method of the organic EL device in Comparative 1, namely, the organic EL device that included no first luminous intensity distribution converter between the light-transmissive substrate 50 and the second electrode 30 but included a hemispheric lens 8 as the second luminous intensity distribution converter. Moreover, a light-shielding mask 81 that is open to fit a diameter of the hemispheric lens 8 was provided on the light-extraction surface of the light-transmissive substrate 50. An emission area of each of the organic EL devices was 10 mm×10 mm. The light-shielding mask 81 had a 4-mm diameter aperture. A diameter of a detection area of the light receiver 9 of the luminous intensity distribution measuring instrument was 10 mm. Emission through the 4-mm diameter aperture was measured in the 10-mm detection area. A specific measuring method was performed as follows.

When selectively measuring an S polarized light component or a P polarized light component of the radiation light, a polarizing plate, which corresponded to the respective polarized light components (the S polarized light component or the P polarized light component) in a light path from emission from the organic EL device to incidence on the light receiver 9, was provided.

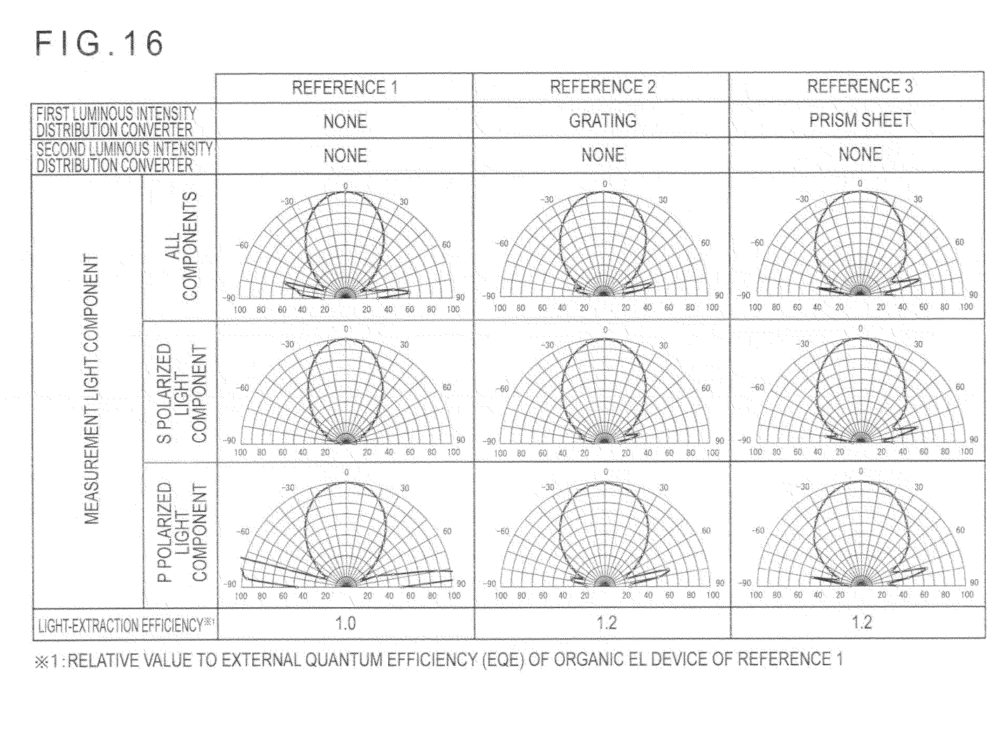

FIG. 10 shows luminous intensity distribution, charts of radiation light having a 520-nm wavelength in comparison to a peak wavelength of radiance spectrum emitted. from the organic EL device in each of References 1 to 3. FIG. 16 shows luminous intensity distribution charts of every measurement light component, namely, all components, the S polarized light component and the P polarized light component, for comparison.

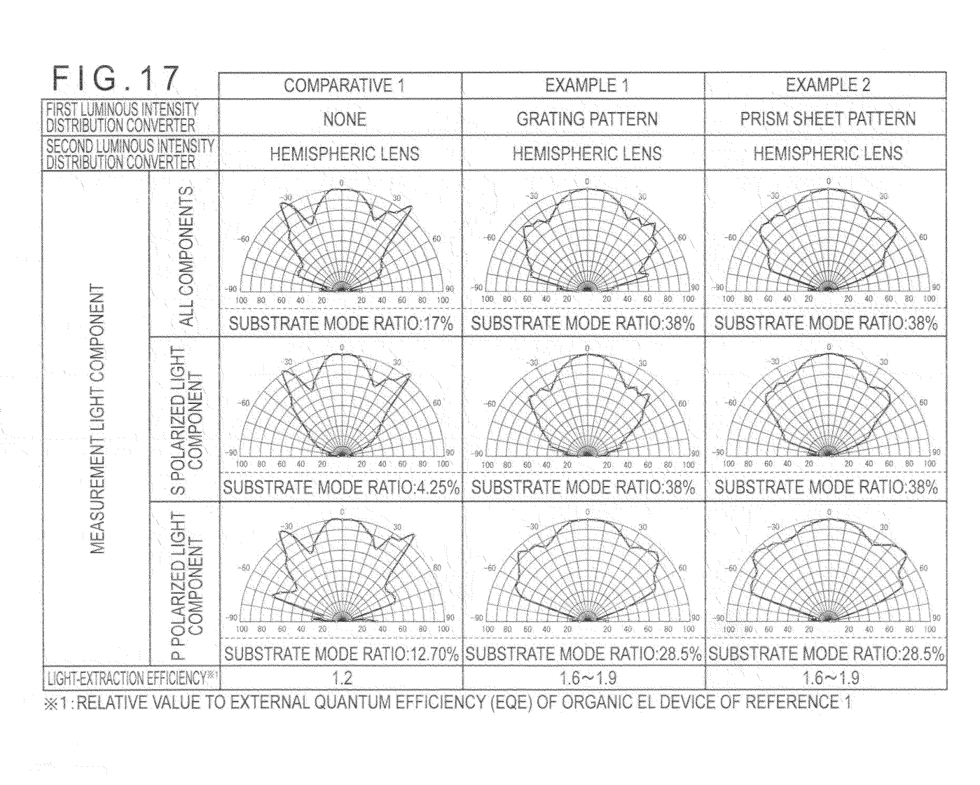

FIG. 17 shows luminous intensity distribution charts of radiation light having a 520-nm wavelength emitted from the organic EL devices in Comparative 1 and Examples 1 and 2. FIG. 17 shows luminous intensity distribution charts of every measurement light component, namely, all components, the S polarized light component and the P polarized light component, for comparison. Further, FIG. 17 shows a ratio of the above-described light in the substrate mode in each of the luminous intensity distribution charts.

FIGS. 16 and 17 show an external quantum efficiency (EQE) of each of the organic EL devices as a relative value when the organic EL device of Reference 1 is used as a reference.

The luminous intensity distribution charts of FIGS. 16 and 17 are standardized according to emission intensity (unit: W/sr⁻¹·nm⁻¹·m⁻²) of a front surface (θ=0 degree) and show angle dependency in the 520-nm emission wavelength.

In the organic EL devices of Comparatives 1 to 3 in FIG. 16, in which the second luminous intensity distribution converter is not provided, emission intensity becomes weaker from the normal direction (θ=0 degree) toward larger angles. Particularly, this tendency is outstanding in the organic EL device of Reference 1 in which the first luminous intensity distribution converter is also not provided. On the other hand, in the organic EL devices of References 2 and 3 in which the first luminous intensity distribution converter is provided, the light in the substrate mode near the larger angles can be guided toward the light-transmissive substrate, so that the relative value of the external quantum efficiency (light-extraction efficiency) reached 1.2 times as much as that in Reference 1.

In the organic EL devices of Examples 1 and 2 shown in FIG. 17 in which the first luminous intensity distribution converter (in a grating pattern or a prism sheet pattern) and the second luminous intensity distribution converter (hemispheric lens) are provided, the emission intensity near the larger angles is stronger than those of the organic EL devices of References 1 to 3 and Comparative 1, the light-extraction efficiency becomes approximately 1.6 times to 1.9 times higher than those in References, and the external quantum efficiency is higher than these in Comparative 1 in which only the second luminous intensity distribution converter is provided and the organic EL devices of References 2 and 3 in which only the first luminous intensity distribution converter is provided. In the organic EL devices of Examples 1 and 2, in comparison between the S polarized light component and the P polarized light component in the luminous intensity distribution charts, a ratio of the light in the substrate mode in the P polarized light component is 28% or more, from which it is found that twice or more of the light in the substrate mode as compared with that of the organic EL device in Comparative 1 (12.20%) was extracted. In the organic EL devices of Examples 1 and 2, twice or more of the light in the substrate mode as compared with that of the organic EL device in Comparative 1 was also extracted with respect to the S polarized light component. As a result, in all component including the S polarized light component and the P polarized light component, in the organic EL devices of Examples 1 and 2, the light in the substrate mode accounts for 38%, and twice or more of the light in the substrate mode as compared with that of the organic EL device in Comparative 1 was also extracted. When the ratio of the light in the substrate mode is increased, the light is efficiently emitted to the outside of the device by the second luminous intensity distribution converter.

In other words, in combining the first luminous intensity distribution converter and the second luminous intensity distribution converter in the organic EL device, functions of the respective converters are synergistically and efficiently exhibited, so that it is found that the external quantum efficiency is outstandingly improved as compared with the devices including only one of the first luminous intensity distribution converter and the second luminous intensity distribution converter.

As shown in FIG. 17, it is found that the organic EL device of Comparative 1 expresses a peak projecting near 35 degrees in the luminous intensity distribution chart and fluctuation of the emission intensity is large in a range of radiation angles. On the other hand, it is found that fluctuation of emission intensity of the organic EL devices in Examples 1 and 2 is smaller than that in Comparative 1. Accordingly, it is found that more uniform emission can be obtained by combining the first luminous intensity distribution converter and the second luminous intensity distribution converter in the organic EL device.

The wording “converts luminous intensity distribution to provide 20% or more of a ratio of light flux of an angular component larger than a total reflection angle defined by a refractive index of a material forming the light-transmissive substrate and a refractive index of a material forming the first luminous intensity distribution converter in a total light flux of radiation light in the light-transmissive substrate” will be described as follows.

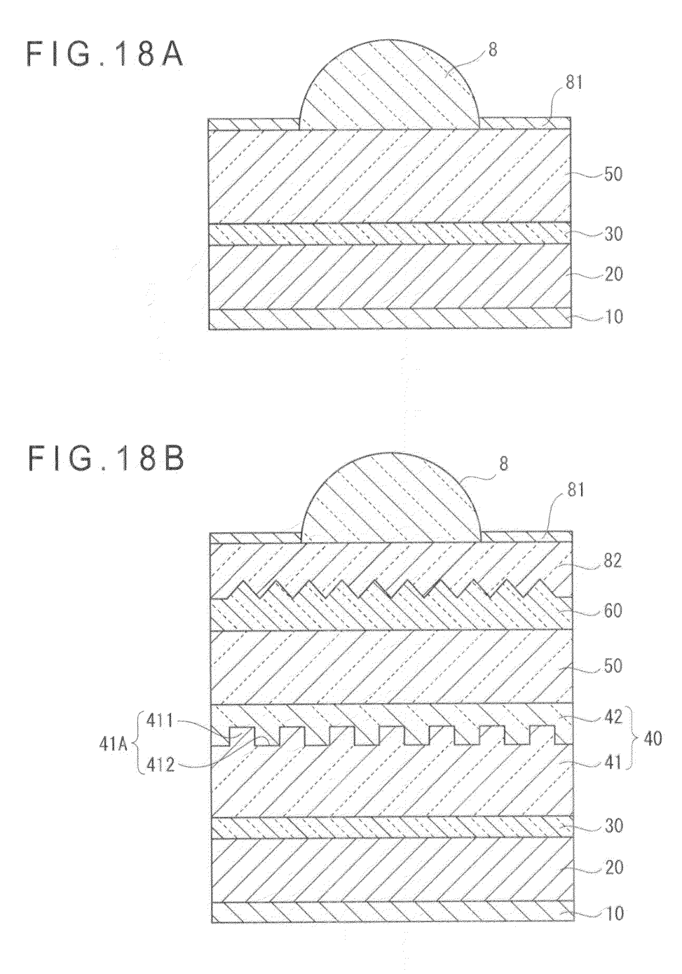

FIGS. 18A and 18B comparatively show arrangements of an organic EL device, in one of which the first luminous intensity distribution converter 40 is not present between the second electrode 30 and the light-transmissive substrate 50 (FIG. 18A) and in the other of which the first luminous intensity distribution converter 40 is present therebetween (FIG. (18B).

FIG. 18A shows the organic EL device without the first luminous intensity distribution converter 40, in which the hemispheric lens 8 (corresponding to the second luminous intensity distribution converter 60) is attached to the light-extraction surface of the light-transmissive substrate 50 and the light-shielding mask 81 is attached thereto in a manner to surround the hemispheric lens 8.

FIG. 18B shows the organic EL device further provided with the first luminous intensity distribution converter 40 and the second luminous intensity distribution converter 60 each having a convexo-concave structure (see FIGS. 6B and 7 as far the convexo-concave structure). Moreover, a layer coated with the index-matching oil 82 (refractive index: 1.5) is formed between the light-extraction surface of the second luminous intensity distribution converter 60 and the light-shielding mask 81.

The above description means that, when a device is formed as in FIG. 18B and luminous intensity distribution of the device is measured to check luminous intensity distribution of the total light flux in the light-transmissive substrate 50, the light flux of the angular component larger than the total reflection angle defined by the refractive index of the material forming the light-transmissive substrate 50 and the refractive index of the material forming the first luminous intensity distribution converter 40 becomes 20% or more.

Moreover, the description that “the first luminous intensity distribution converter converts luminous intensity distribution for a light flux confined in the light-transmissive substrate when there is no first luminous intensity distribution converter between the second electrode and the light-transmissive substrate to account for 20% or more of a total light flux of the radiation light measured in the outside of the organic EL device when the first luminous intensity distribution converter is present between the second electrode and the light-transmissive substrate” will be explained as follows.

This description means that the light flux emitted from the organic EL device of FIG. 18B becomes 1.2 times or more as much as the light flux emitted from the organic EL device of FIG. 18A, in comparison between luminous intensity distributions of the devices formed as shown in FIGS. 18A and 18B.

### Actual Measurement Method of Luminous Intensity Distribution

A diameter of a detection area of the light receiver 9 of the luminous intensity distribution measuring instrument is 10 mm. Since emission through the 4-mm diameter aperture is measured in the 10-mm detection area, such a measurement without variance in a projection area becomes possible when measured from a front surface and when obliquely measured.

As a result of the measurement using a 4-mm diameter hemispheric lens, a light-extraction efficiency was improved. Accordingly, even when radiation from a single lens having a diameter of several 10 μm, which is within a range in which a phenomenon is handleable in geometric optics, is measured, it is easily considered that the same advantages as in the measurement using the 4-mm diameter hemispheric lens is obtainable.

Accordingly, when the second luminous intensity distribution converter in Comparative 1 and Examples 1 and 2 is provided by a hemispheric lens, measurements of the luminous intensity distribution of the device arranged (processed) as shown in FIGS. 18A and 18B become substantially the same as luminous intensity distribution of the device before the arrangement (processing) as shown in FIG. 15.

The convexo-concave shapes described in the above exemplary embodiments include the shapes shown in the above drawings.

What is claimed is:

1. An organic electroluminescence device comprising:
a first electrode;
a second electrode opposed to the first electrode;
an organic compound layer that is provided between the first electrode and the second electrode and at least comprises an emitting layer;
a light-transmissive substrate opposed to a surface of the second electrode facing the first electrode;
a first luminous intensity distribution converter that is provided between the second electrode and the light-transmissive substrate, the first luminous intensity distribution converter having a first convexo-concave structure and converting a luminous intensity distribution of a radiation light emitted from the emitting layer to emit the radiation light to the light-transmissive substrate; and
a second luminous intensity distribution converter that is provided to a first surface of the light-transmissive substrate opposed to a second surface thereof facing the first luminous intensity distribution converter, the second luminous intensity distribution converter having a second convexo-concave structure and converting luminous intensity distribution of the radiation light having entered the light-transmissive substrate to emit the radiation light to an outside of the organic electroluminescence device, wherein
the first luminous intensity distribution converter converts the luminous intensity distribution for a light flux of an angular component larger than a total reflection angle to account for 20% or more of a ratio of a total light flux of the radiation light in the light-transmissive substrate, the total reflection angle being defined by a refractive index of a material forming the light-transmissive substrate and a refractive index of a material forming the first luminous intensity distribution converter.

2. An organic electroluminescence device comprising:
a first electrode;
a second electrode opposed to the first electrode;
an organic compound layer that is provided between the first electrode and the second electrode and at least comprises an emitting layer;
a light-transmissive substrate opposed to a surface of the second electrode facing the first electrode;
a first luminous intensity distribution converter that is provided between the second electrode and the light-transmissive substrate, the first luminous intensity distribution converter converting a luminous intensity distribution of a radiation light emitted from the emitting layer to emit the radiation light to the light-transmissive substrate; and
a second luminous intensity distribution converter that is provided to a first surface of the light-transmissive substrate opposed to a second surface thereof facing the first luminous intensity distribution converter, the second luminous intensity distribution converter having a second convexo-concave structure and converting the luminous intensity distribution of the radiation light having entered the light-transmissive substrate to emit the radiation light to an outside of the organic electroluminescence device, wherein
the first luminous intensity distribution converter converts the luminous intensity distribution for a light flux confined in the light-transmissive substrate when there is no first luminous intensity distribution converter between the second electrode and the light-transmissive substrate to account for 20% or more of a total light flux of the radiation light measured in an outside of the organic EL device when the first luminous intensity distribution converter is present between the second electrode and the light-transmissive substrate.

3. An organic electroluminescence device comprising:
a first electrode;
a second electrode opposed to the first electrode;
an organic compound layer that is provided between the first electrode and the second electrode and at least comprises an emitting layer,
a light-transmissive substrate opposed to a surface of the second electrode facing the first electrode;
a first luminous intensity distribution converter that is provided between the second electrode and the light-transmissive substrate, the first luminous intensity distribution converter converting a luminous intensity distribution of a radiation light emitted from the emitting layer to emit the radiation light to the light-transmissive substrate; and
a second luminous intensity distribution converter that is provided to a first surface of the light-transmissive substrate opposed to a second surface thereof facing the first luminous intensity distribution converter, the second luminous intensity distribution converter having a second convexo-concave structure and converting the luminous intensity distribution of the radiation light having entered the light-transmissive substrate to emit the radiation light to an outside of the organic electroluminescence device, wherein
the first luminous intensity distribution converter comprises: a high refractive layer that is provided near the second electrode; and a low refractive layer that is provided near the light-transmissive substrate and is adjacent to the high refractive layer, and
a plurality of convexo-concave units each provided by a convex portion and a concave portion are provided at an interface between the high refractive layer and the low refractive layer.

4. The organic electroluminescence device according to claim 1, wherein
the second convexo-concave structure comprises a plurality of second convex portions projecting toward the outside of the organic electroluminescence device and a plurality of second concave portions provided between the second convex portions, and
the plurality of second convex portions are formed with a pitch therebetween which is equal to or more than an optical coherence length.

5. The organic electroluminescence device according to claim 2, wherein
the second convexo-concave structure comprises a plurality of second convex portions projecting toward the outside of the organic electroluminescence device and a plurality of second concave portions provided between the second convex portions, and
the plurality of second convex portions are formed with a pitch therebetween which is equal to or more than an optical coherence length.

6. The organic electroluminescence device according to claim 3, wherein
the second convexo-concave structure comprises a plurality of second convex portions projecting toward the outside of the organic electroluminescence device and a plurality of second concave portions provided between the second convex portions, and
the plurality of second convex portions are formed with a pitch therebetween which is equal to or more than an optical coherence length.

7. The organic electroluminescence device according to claim 4, wherein
the plurality of second convex portions each project in a form of a column, a cone or a hemisphere and are misaligned instead of a grating arrangement.

8. The organic electroluminescence device according to claim 5, wherein
the plurality of second convex portions each project in a form of a column, a cone or a hemisphere and are misaligned instead of a grating arrangement.

9. The organic electroluminescence device according to claim 6, wherein
the plurality of second convex portions each project in a form of a column, a cone or a hemisphere and are misaligned instead of a grating arrangement.
